(19) United States
(12) Patent Application Publication
(10) Pub. No.: US 2025/0261540 A1
(43) Pub. Date: Aug. 14, 2025

(54) DISPLAY DEVICE AND METHOD FOR MANUFACTURING THE SAME

(71) Applicant: Samsung Display Co., LTD., Yongin-si (KR)

(72) Inventors: Soo Jung CHAE, Yongin-si (KR); Da Hye PARK, Yongin-si (KR); Tae Sun PARK, Yongin-si (KR); Zu Seok OH, Yongin-si (KR); Jae Hyoung YOUN, Yongin-si (KR); Je Min LEE, Yongin-si (KR)

(73) Assignee: Samsung Display Co., LTD., Yongin-si (KR)

(21) Appl. No.: 18/909,322

(22) Filed: Oct. 8, 2024

(30) Foreign Application Priority Data
Feb. 13, 2024 (KR) 10-2024-0020533

(51) Int. Cl. H10K 59/80; H10K 59/12; H10K 59/122; H10K 59/35

(52) U.S. Cl. CPC H10K 59/871; H10K 59/1201; H10K 59/122; H10K 59/353

(57) ABSTRACT

A display device comprises a substrate, a circuit layer, an element layer, and a sealing layer. The display device includes a display area, a non-display area, a hole area, and a hole peripheral area. The circuit layer includes an interlayer insulating layer, a first planarization layer, roof portions surrounding the hole area, a second planarization layer covering the roof portions, and one or more sealing auxiliary grooves positioned between adjacent ones of the roof portions. Each of the one or more sealing auxiliary grooves includes a first auxiliary groove penetrating through the second planarization layer and a second auxiliary groove formed concavely in the first planarization layer. A slope of a side surface of the second auxiliary groove with respect to the substrate is steeper than a slope of a side surface of the first auxiliary groove with respect to the substrate.

### CROSS-REFERENCE TO RELATED APPLICATION

This application claims priority to and benefits of Korean Patent Application No. 10-2024-0020533 under 35 U.S.C. § 119, filed on Feb. 13, 2024 in the Korean Intellectual Property Office (KIPO), the contents of which in its entirety are incorporated herein by reference.

### BACKGROUND

### 1. Technical Field

The disclosure generally relates to a display device and a method for manufacturing the same. More specifically, the disclosure relates to a display device having a light transmitting hole disposed in a hole area surrounded by the display area and a method for manufacturing the same.

### 2. Description of the Related Art

The need for display devices that show images in a variety of formats is growing as the information society progresses. For instance, the display device is used in many different electronic products, including smart TVs, digital cameras, laptops, cellular phones, and navigation devices.

The display device may be a flat panel display device such as a liquid crystal display device, a field emission display device, or a light emitting display device. Here, the light emitting display device may include an organic light emitting display device including an organic light emitting element, an inorganic light emitting display device including an inorganic light emitting element such as an inorganic semiconductor, and a micro or nano light emitting display device including a micro or nano light emitting element.

The organic light emitting display device displays an image using light emitting elements each including a light emitting layer made of an organic light emitting material. As such, as the organic light emitting display device implements image display using self-light emitting elements, the organic light emitting display device may have relatively superior performance in terms of power consumption, response speed, emission efficiency, luminance, and wide viewing angle compared to other display devices.

One surface of the display device may be a display surface including a display area where an image is displayed. Light emitting areas that emit light with respective luminance and color may be arranged in the display area.

### SUMMARY

The display device may include a light transmitting hole disposed in a hole area surrounded by the display area.

An element layer may include light emitting elements disposed in light emitting areas, and each of the light emitting elements may include a first common layer between an anode electrode and a light emitting layer, and a second common layer between the light emitting layer and a cathode electrode.

As the cathode electrode and the second common layer are entirely disposed in the display area, the cathode electrode and the second common layer may also be disposed in the hole area surrounded by the display area and a hole peripheral area between the hole area and the display area.

Accordingly, oxygen or moisture may relatively readily permeate by the second common layer disposed adjacent to the light transmitting hole, thereby drastically shortening the lifespan of the display device.

Aspects of the disclosure provide a display device that may improve the lifespan by delaying permeation of oxygen or moisture through a second common layer in a hole peripheral area, and a method for manufacturing the same.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an aspect of the disclosure, a display device comprises a substrate; a circuit layer disposed on the substrate; an element layer disposed on the circuit layer; and a sealing layer disposed on the element layer. The display device includes a display area in which light emitting areas are arranged; a non-display area disposed adjacent to the display area; a hole area surrounded by the display area; and a hole peripheral area disposed between the hole area and the display area. The circuit layer includes an interlayer insulating layer disposed on the substrate; a first planarization layer disposed on the interlayer insulating layer; roof portions disposed in the hole peripheral area on the first planarization layer and surrounding the hole area; a second planarization layer disposed on the first planarization layer and covering the roof portions; and one or more sealing auxiliary grooves positioned adjacent ones of the roof portions. Each of the one or more sealing auxiliary grooves includes a first auxiliary groove penetrating through the second planarization layer; and a second auxiliary groove formed concavely in the first planarization layer. A slope of a side surface of the second auxiliary groove with respect to the substrate is steeper than a slope of a side surface of the first auxiliary groove with respect to the substrate.

In a direction in which the roof portions face each other, at least a portion of an edge of each of the roof portions may protrude more than the second auxiliary groove of the one or more sealing auxiliary grooves. An undercut structure may be positioned between the roof portions and the second auxiliary groove of the one or more sealing auxiliary grooves.

The display device may further comprise a light transmitting hole formed in the hole area and penetrating through the substrate, the circuit layer, the element layer, and the sealing layer.

The display device may comprise one or more hole peripheral dams disposed between the roof portions and the hole area and surrounding the hole area. The one or more hole peripheral dams may be spaced apart from each of the first planarization layer, the second planarization layer, and the hole area. The sealing layer may include a first sealing layer disposed on the element layer; a second sealing layer disposed on the first sealing layer and overlapping the display area; and a third sealing layer disposed on the first sealing layer and covering the second sealing layer. The second sealing layer may extend to the one or more hole peripheral dams and include an organic insulating material spaced from the hole area. The first sealing layer and the third sealing layer may include an inorganic insulating material, and contact each other in an area between the one or more hole peripheral dams of the hole peripheral area and the hole area. The sealing roof portions may overlap the second sealing layer.

The element layer may include anode electrodes disposed in the light emitting areas; a pixel defining layer disposed in a non-light emitting area adjacent to the light emitting areas and covering an edge of each of the anode electrodes; a spacer layer disposed on a portion of the pixel defining layer; first common layers disposed on the anode electrodes; light emitting layers disposed on the first common layers; a second common layer disposed in the display area and the hole peripheral area and covering the pixel defining layer, the spacer layer, and the light emitting layers; and a cathode electrode disposed on the second common layer.

The element layer may further include a separation groove disposed around each of the light emitting areas and formed concavely in the pixel defining layer.

The separation groove may be parallel to each side of an edge of each of the light emitting areas. The second common layer may be disconnected in the separation groove.

A portion of the second common layer disposed in the hole peripheral area may include first division portions disposed on the second planarization layer and overlapping the roof portions; and one or more second division portions disposed within the second auxiliary groove of the one or more sealing auxiliary grooves and spaced apart from the first division portions.

Within the second auxiliary groove of the one or more sealing auxiliary grooves, the cathode electrode may contact the first planarization layer.

Each of the one or more hole peripheral dams may include dam layers.

Each of the two or more dam layers and one of the first planarization layer, the second planarization layer, the pixel defining layer, and the spacer layer may be disposed on a same layer.

In each of an area between the first planarization layer and the second planarization layer, and the one or more hole peripheral dams, an area between the one or more hole peripheral dams, and an area between the one or more hole peripheral dams and the hole area, the first sealing layer may contact the interlayer insulating layer.

The circuit layer may further include a first source drain conductive layer disposed in the display area on the interlayer insulating layer and covered by the first planarization layer; and a second source drain conductive layer disposed in the display area on the first planarization layer and covered by the second planarization layer. The roof portions and the second source drain conductive layer may be disposed on a same layer.

The circuit layer may further include a buffer layer disposed on the substrate; a first gate insulating layer disposed on the buffer layer; and a second gate insulating layer disposed on the first gate insulating layer. The interlayer insulating layer may be disposed on the second gate insulating layer. The light transmitting hole may penetrate through the third sealing layer, the first sealing layer, the cathode electrode, the second common layer, the interlayer insulating layer, the second gate insulating layer, the first gate insulating layer, the buffer layer, and the substrate.

According to an aspect of the disclosure, a method for manufacturing a display device comprises preparing a substrate including a display area in which light emitting areas are arranged; a non-display area disposed adjacent to the display area; a hole area surrounded by the display area; and a hole peripheral area disposed between the hole area and the display area; disposing a circuit layer on the substrate; disposing an element layer on the circuit layer; disposing a sealing layer on the element layer; and forming a light transmitting hole sequentially penetrating through the substrate, the circuit layer, the element layer, and the sealing layer in the hole area. The disposing of the element layer includes disposing anode electrodes of the light emitting areas on the circuit layer; disposing a pixel defining layer of a non-light emitting area disposed adjacent to the light emitting areas on the circuit layer, and disposing a spacer layer on a portion of the pixel defining layer; forming a sealing auxiliary groove in the hole peripheral area and a separation groove in the display area; disposing first common layers on the anode electrodes; disposing light emitting layers on the first common layers; disposing a second common layer covering the pixel defining layer, the spacer layer, and the light emitting layers in the display area and the hole peripheral area; and disposing a cathode electrode on the second common layer.

The disposing of the circuit layer may include disposing an interlayer insulating layer on the substrate; disposing a first source drain conductive layer in the display area on the interlayer insulating layer; disposing a first planarization layer covering the first source drain conductive layer on the interlayer insulating layer; disposing a second source drain conductive layer in the display area and roof portions in the hole peripheral area on the first planarization layer; and disposing a second planarization layer covering the second source drain conductive layer and the roof portions on the first planarization layer. In the disposing of the second source drain conductive layer and the roof portions, the roof portions surround the hole area. In the forming of the sealing auxiliary groove and the separation groove. The sealing auxiliary groove includes a first auxiliary groove positioned between the roof portions and penetrating through the second planarization layer, and a second auxiliary groove formed concavely in the first planarization layer. The separation groove is positioned to surround each of the light emitting areas and is formed concavely in the pixel defining layer.

The forming of the sealing auxiliary groove and the separation groove may include disposing an oxide material layer covering the pixel defining layer in the display area and the second planarization layer in the hole peripheral area, and disposing a first photo mask on the oxide material layer; preparing a first oxide mask layer by partially removing the oxide material layer through the first photo mask; forming a first temporary groove penetrating through the second planarization layer and a second temporary groove formed concavely in the first planarization layer by partially removing the second planarization layer and the first planarization layer in the hole peripheral area through the first oxide mask layer; preparing a second photo mask by partially removing the first photo mask; preparing a second oxide mask layer by partially removing the first oxide mask layer through the second photo mask; forming the separation groove by partially removing the pixel defining layer through the second oxide mask layer, and forming the sealing auxiliary groove by additionally removing the second planarization layer and the first planarization layer through the second oxide mask layer, the first temporary groove, and the second temporary groove; and removing the second photo mask and the second oxide mask layer.

In the disposing of the oxide material layer and the first photo mask, the first photo mask may include a first transmitting portion overlapping an area between the roof portions; a first blocking portion overlapping a portion of the non-light emitting area adjacent to each of the light emitting areas and having a first thickness; and a second blocking portion excluding the first transmitting portion and the first blocking portion and having a second thickness greater than the first thickness. In the preparing of the first oxide mask layer, the first oxide mask layer includes a first opening corresponding to the first transmitting portion. In the forming of the first temporary groove and the second temporary groove, the first temporary groove is formed by removing a portion of the second planarization layer through the first transmitting portion and the first opening, and the second temporary groove may be formed by removing a portion of the first planarization layer through the first transmitting portion, the first opening, and the first temporary groove.

In the preparing of the second photo mask, the second photo mask may include a second transmitting portion prepared by removing a portion of the second blocking portion disposed around the first transmitting portion; a third transmitting portion prepared by removing the first blocking portion; and a third blocking portion prepared as a remainder of the second blocking portion and having a third thickness smaller than the second thickness. In the preparing of the second oxide mask layer, the second oxide mask layer includes a second opening corresponding to the second transmitting portion and a third opening corresponding to the third transmitting portion. In the forming of the sealing auxiliary groove and the separation groove, the first auxiliary groove may be prepared by removing a portion of the second planarization layer disposed around the first temporary groove through the second opening, the second auxiliary groove may be prepared by removing a portion of the first planarization layer disposed around the second temporary groove through the second opening and the first auxiliary groove, and the separation groove is prepared by removing a portion of the pixel defining layer through the third opening.

In the forming of the sealing auxiliary groove and the separation groove, a slope of a side surface of the second auxiliary groove may be steeper than a slope of a side surface of the first auxiliary groove with respect to the substrate, in a direction in which the roof portions face each other, at least a portion of an edge of each of the roof portions may protrude more than the second auxiliary groove of the sealing auxiliary groove, and an undercut structure may be positioned between the roof portions and the second auxiliary groove of the sealing auxiliary groove.

In the disposing of the second common layer, a portion of the second common layer disposed in the hole peripheral area may include first division portions disposed on the second planarization layer and overlapping the roof portions; and one or more second division portions disposed within the second auxiliary groove of the sealing auxiliary groove and spaced apart from the first division portions. In the disposing of the cathode electrode, the cathode electrode may contact the first planarization layer within the second auxiliary groove of the sealing auxiliary groove.

The display device according to embodiments includes a substrate, a circuit layer disposed on the substrate, an element layer disposed on the circuit layer, and a sealing layer disposed on the element layer.

The substrate includes a display area in which light emitting areas are arranged, a non-display area disposed around the display area, a hole area surrounded by the display area, and a hole peripheral area disposed between the hole area and the display area.

The circuit layer may include an interlayer insulating layer disposed on the substrate, a first planarization layer disposed on the interlayer insulating layer, roof portions disposed in the hole peripheral area on the first planarization layer and sequentially surrounding the hole area, a second planarization layer disposed on the first planarization layer and covering the roof portions, and one or more sealing auxiliary grooves positioned between the roof portions.

Each of the one or more sealing auxiliary grooves may include a first auxiliary groove penetrating through the second planarization layer, and a second auxiliary groove formed concavely in the first planarization layer.

A slope of a side surface of the second auxiliary groove may be steeper than a slope of a side surface of the first auxiliary groove.

According to embodiments, in a direction in which the roof portions face each other, at least a portion of an edge of each of the roof portions may protrude more than the one or more sealing auxiliary grooves. For example, an undercut structure may be formed between the roof portions and the second auxiliary groove of the one or more sealing auxiliary grooves.

According to embodiments, the element layer may include anode electrodes disposed in the light emitting areas, a pixel defining layer disposed in a non-light emitting area between the light emitting areas and covering an edge of each of the anode electrodes, a spacer layer disposed on a portion of the pixel defining layer, first common layers disposed on the anode electrodes, light emitting layers disposed on the first common layers, a second common layer disposed in the display area and the hole peripheral area and covering the pixel defining layer, the spacer layer, and the light emitting layers, and a cathode electrode disposed on the second common layer.

As described above, according to embodiments, since the roof portions and the one or more sealing auxiliary grooves are disposed in the hole peripheral area, a portion of the second common layer disposed in the hole peripheral area may be separated or disconnected by the undercut structure disposed between the roof portions and the second auxiliary groove.

For example, a portion of the second common layer disposed in the hole peripheral area may include first division portions disposed on the second planarization layer and overlapping the roof portions, and one or more second division portions disposed within the second auxiliary groove of the one or more sealing auxiliary grooves and spaced apart from the first division portions.

In other words, the one or more second division portions may be separated from the first division portions by the undercut structure disposed between the roof portions and the second auxiliary groove.

Accordingly, an occurrence of a permeation path of oxygen or moisture through the second common layer disposed in the hole peripheral area may be delayed. As a result, the lifespan of the display device including the light transmitting hole may be improved.

Further, according to embodiments, the element layer may further include a separation groove disposed around each of the light emitting areas and formed concavely in the pixel defining layer.

Due to a slope of a side surface of the separation groove, the second common layer may be disposed with a non-uniform thickness. For example, the second common layer may have a relatively thin thickness at the separation groove, and thus, the second common layer may be disconnected or separated by the separation groove.

As a result, a leakage current through the second common layer may be reduced between neighboring light emitting areas among the light emitting areas, and thus an image quality of the display device may be improved.

A method for manufacturing a display device according to embodiments may include preparing a substrate, disposing a circuit layer on the substrate, disposing an element layer on the circuit layer, disposing a sealing layer on the element layer, and forming a light transmitting hole in a hole area.

The disposing of the element layer may include disposing anode electrodes, disposing a pixel defining layer and a spacer layer, forming a sealing auxiliary groove and a separation groove, disposing first common layers, disposing a second common layer, and disposing a cathode electrode.

According to embodiments, since the sealing auxiliary groove and the separation groove are formed together, the number of mask processes may be reduced. Therefore, even if the sealing auxiliary groove and the separation groove are included, the number of manufacturing processes of the display device may be reduced.

However, effects according to the embodiments of the disclosure are not limited to those exemplified above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view illustrating a display device according to embodiments;

FIG. 2 is a schematic plan view illustrating the display device of FIG. 1;

FIG. 3 is a schematic cross-sectional view taken along line A-A′ of FIG. 2;

FIG. 4 is a schematic layout view illustrating portion B of FIG. 2;

FIG. 5 is a schematic diagram of an equivalent circuit illustrating a light emitting pixel driver of FIG. 4;

FIG. 6 is a schematic cross-sectional view illustrating first and sixth transistors and a light emitting element of FIG. 5;

FIG. 7 is a schematic layout view illustrating portion C of FIG. 2;

FIG. 8 is a schematic cross-sectional view taken along line D-D′ of FIG. 7 according to an embodiment;

FIG. 9 is a schematic enlarged view illustrating portion D of FIG. 8;

FIG. 10 is a schematic cross-sectional view taken along line D-D′ of FIG. 7 according to an embodiment;

FIGS. 11, 12, 13, and 14 are schematic flowcharts illustrating a method for manufacturing a display device according to embodiments; and

FIGS. 15, 16, 17, 18, 19, 20, 21, 22, 23, 24 and 25 are process diagrams illustrating some of the steps of FIGS. 11, 12, 13, and 14.

### DETAILED DESCRIPTION OF THE EMBODIMENTS

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

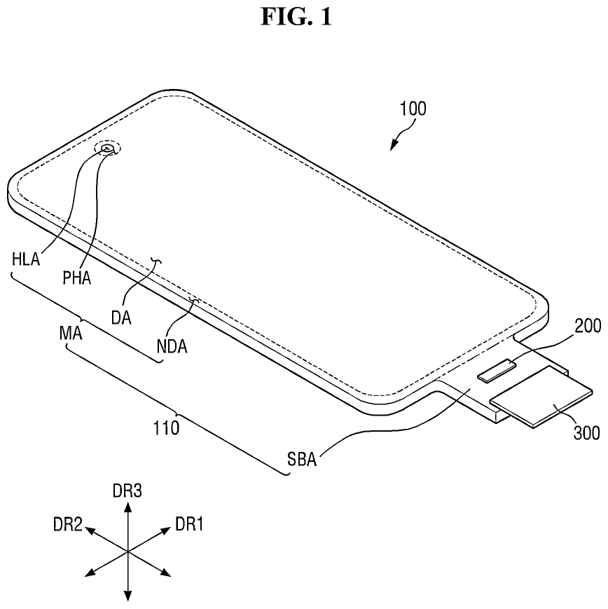

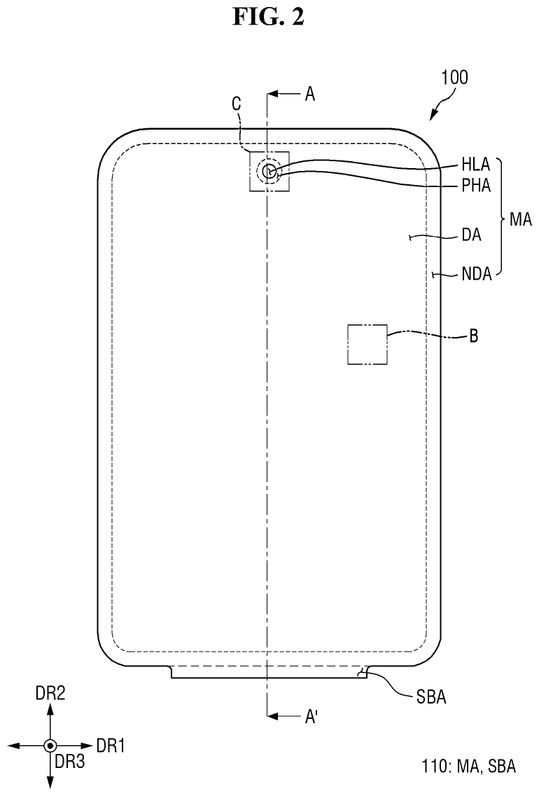

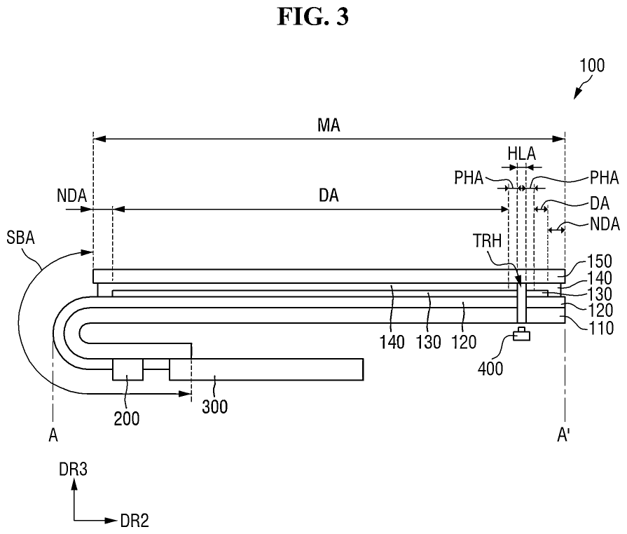

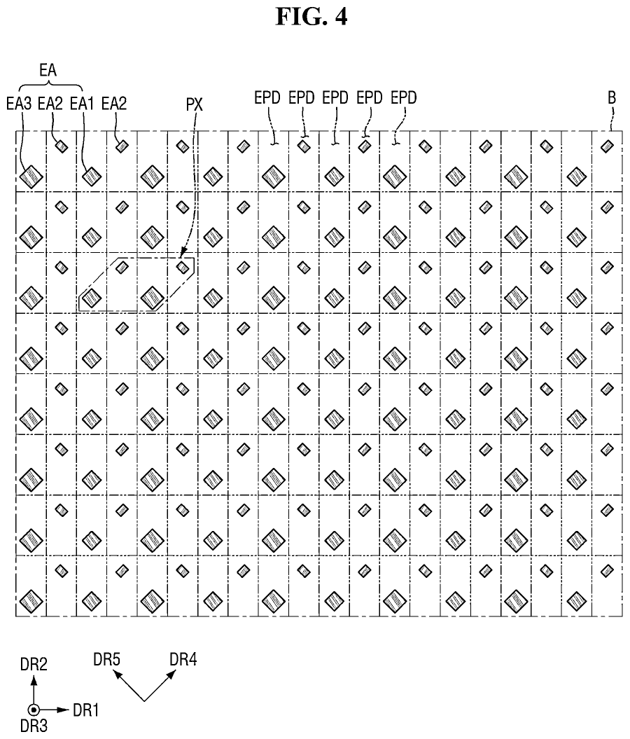

FIG. 1 is a schematic perspective view illustrating a display device according to embodiments. FIG. 2 is a schematic plan view illustrating the display device of FIG. 1. FIG. 3 is a cross-sectional view taken along line A-A′ of FIG. 2. FIG. 4 is a layout view illustrating portion B of FIG. 2.

Referring to FIGS. 1 and 2, a display device 100 is a device that displays a moving image or a still image, and may be used as a display screen of each of various products such as a television, a laptop computer, a monitor, a billboard, and an Internet of Things (IOT) device as well as portable electronic devices such as a mobile phone, a smartphone, a tablet personal computer (PC), a smartwatch, a watch phone, a mobile communication terminal, an electronic organizer, an electronic book, a portable multimedia player (PMP), a navigation device, and an ultra mobile PC (UMPC).

The display device 100 may be a light emitting display device such as an organic light emitting display device using an organic light emitting diode, a quantum dot light emitting display device including a quantum dot light emitting layer, an inorganic light emitting display device including an inorganic semiconductor, and a micro light emitting display device using a micro or nano light emitting diode (micro or nano LED). Hereinafter, the description will be made mainly based on the fact that the display device 100 is an organic light emitting display device. However, the disclosure is not limited thereto and may be applied to display devices including organic insulating materials, organic light emitting materials, and metal materials.

The display device 100 may be formed to be flat, but is not limited thereto. For example, the display device 100 may include curved surface portions formed at left and right distal ends thereof and having a constant curvature or a variable curvature. The display device 100 may be flexibly formed to be curved, bent, folded, or rolled.

As illustrated in FIGS. 1, 2, and 3, the display device 100 may include a substrate 110.

The substrate 110 may include a main area MA corresponding to a display surface of the display device 100 and a sub-area SBA protruding from a portion of the main area MA.

As illustrated in FIG. 2, the main area MA may include a display area DA and a non-display area NDA disposed around the display area DA.

The display area DA may be formed in a rectangular plane having short sides extending in a first direction DR1 and long sides extending in a second direction DR2 intersecting the first direction DR1. In another example, the display area DA may have short sides extending in a second direction DR2 and long sides extending in the first direction DR1. A corner where the short side in the first direction DR1 and the long side in the second direction DR2 meet may be rounded to have a predetermined curvature or may be formed at a right angle. The planar shape of the display area DA is not limited to the quadrangular shape, and the display area DA may be formed in other polygonal, circular, or oval shapes.

The non-display area NDA may be disposed at an edge of the main area MA to surround the display area DA.

The sub-area SBA may be an area protruding from the non-display area NDA of the main area MA in the second direction DR2.

FIGS. 2 and 3 illustrate the display device 100 with a portion of the sub-area SBA curved.

As illustrated in FIGS. 2 and 3, a portion of the sub-area SBA (e.g., the attached portion to the main area MA) may be bent into a curved shape so that the other portion of the sub-area SBA (e.g., the non-attached portion to the main area MA) may be disposed on a rear surface of the substrate 110 opposite to the display surface.

Referring to FIG. 3, the display device 100 according to embodiments may include a substrate 110, a circuit layer 120 disposed on the substrate 110, an element layer 130 disposed on the circuit layer 120, and a sealing layer 140 disposed on the element layer 130 and partially disposed on the circuit layer 120.

The display device 100 according to embodiments may further include a cover window 150 disposed on the sealing layer 140. The cover window 150 may be bonded to face the substrate 110. As another example, the cover window 150 may be coupled to a bracket under a rear surface of the substrate 110. The bracket may accommodate the substrate 110 and a display driving circuit 300.

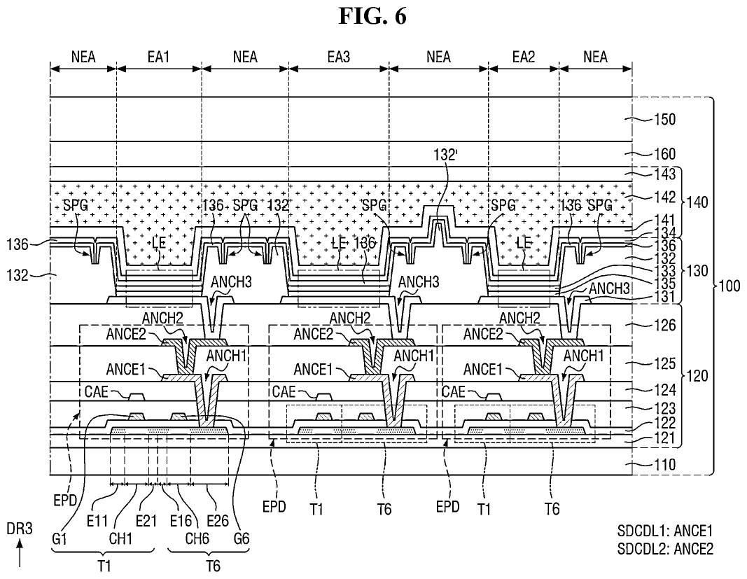

The display device 100 according to embodiments may further include a touch sensor layer (160 in FIG. 6) disposed on the sealing layer 140.

The display device 100 according to embodiments may further include a polarizing layer disposed on the sealing layer 140 to reduce reflection of external light.

The substrate 110 may be made of an insulating material such as a polymer resin. For example, the substrate 110 may be made of polyimide. The substrate 110 may be a flexible substrate that may be bent, folded, and rolled.

As another example, the substrate 110 may be made of an insulating material such as glass.

The substrate 110 may include a main area MA and a sub-area SBA. The main area MA may include a display area DA and a non-display area NDA.

The circuit layer 120 may include conductive layers, one or more semiconductor layers, and insulating layers interposed therebetween. The circuit layer 120 may include transistors provided with one or more semiconductor layers and one or more conductive layers, and signal lines each provided with at least one of the conductive layers.

The element layer 130 may include light emitting elements that emit light according to a driving current applied from the circuit layer 120.

The sealing layer 140 may cover the circuit layer 120 and the element layer 130, and may block permeation of oxygen or moisture into the element layer 130.

The cover window 150 may include a light transmitting material. The cover window 150 may be made of an inorganic material such as glass or be made of an organic material such as plastic or a polymer material. However, the material of the cover window is not limited to thereto.

Referring to FIG. 4, the display area DA of the substrate 110 of the display device 100 according to embodiments may include light emitting areas EA. The display area DA may further include a non-light emitting area disposed in a spaced portion between the light emitting areas EA.

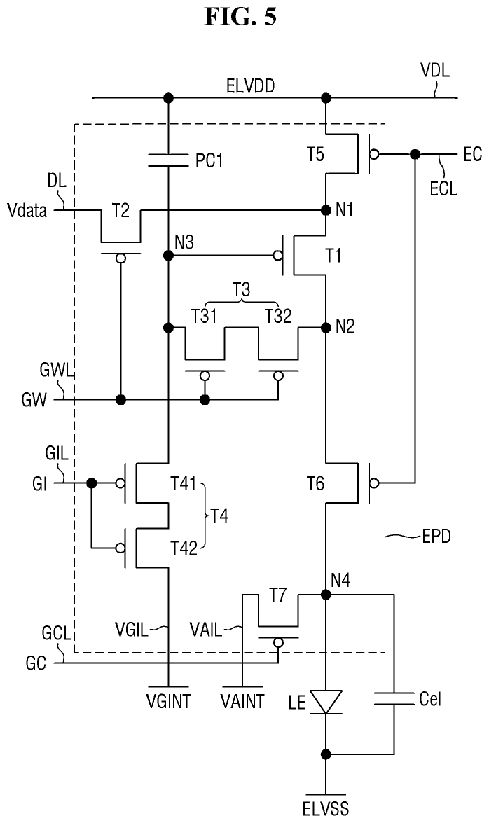

The element layer (130 in FIG. 3) may include light emitting elements (LE in FIG. 5), and each of the emitting elements may be disposed in the light emitting areas EA.

The circuit layer (120 in FIG. 3) may include light emitting pixel drivers EPD arranged to be parallel to each other in the first direction DR1 and the second direction DR2 in the main area MA. The light emitting pixel drivers EPD may be electrically connected to each of the light emitting elements (LE in FIG. 5) of the element layer 130, respectively.

The light emitting areas EA may have a rhombic planar shape or a rectangular planar shape. However, the planar shape of the light emitting areas EA is not limited to that illustrated in FIG. 4. For example, the light emitting areas EA may have a polygonal planar shape such as a square, pentagon, or hexagon, or a circular or oval planar shape including curved edges.

The light emitting areas EA may include first light emitting areas EA1 that emit light of a first color in a first wavelength band, second light emitting areas EA2 that emit light of a second color in a second wavelength band which is lower than first wavelength band, and third light emitting areas EA3 that emit light of a third color in a third wavelength band which is lower than the second wavelength band.

As an example, the first color may be red in a wavelength band of about 600 nm to about 750 nm. The second color may be green in a wavelength band of about 480 nm to about 560 nm. The third color may be blue in a wavelength band of about 370 nm to about 460 nm.

The first light emitting areas EA1 and the third light emitting areas EA3 may be alternately disposed in at least one of the first direction DR1 and the second direction DR2.

The second light emitting areas EA2 may be arranged to be parallel to each other in at least one of the first direction DR1 and the second direction DR2.

The second light emitting areas EA2 may be disposed adjacent to the first light emitting areas EA1 and the third light emitting areas EA3 in diagonal directions DR4 and DR5 intersecting the first and second directions DR1 and DR2. In this case, the third light emitting areas EA3 may be disposed adjacent to the second light emitting areas EA2 in diagonal directions DR4 or DR5. Similarly, the first light emitting areas EA1 may be disposed adjacent to the second light emitting areas EA2 in diagonal directions DR4 or DR5.

As illustrated in FIG. 4, the size of each of the second emitting areas EA2 may be larger than that of each of the first light emitting areas EA1. The size of each of the first emitting areas EA1 may be larger than that of each of the third light emitting areas EA3.

Pixels PX that display different luminance and color may be provided by the first light emitting area EA1, the second light emitting area EA2, and the third light emitting area EA3 adjacent to each other among the light emitting areas EA.

In other words, the pixels PX may be basic units that display various colors, including white, at predetermined luminance.

Each of the pixels PX may include at least one first light emitting area EA1, at least one second light emitting area EA2, and at least one third light emitting area EA3 adjacent to each other. For example, each of the pixels PX may include one first light emitting area EA1, two second light emitting areas EA2, and one third light emitting area EA3. Accordingly, each of the pixels PX may display various colors through mixing of light emitted from the first, second, and third light emitting areas EA1, EA2, and EA3 adjacent to each other.

FIG. 5 is a schematic diagram of an equivalent circuit illustrating a light emitting pixel driver of FIG. 4.

Referring to FIG. 5, one of the light emitting elements LE of the element layer 130 may be electrically connected between one of the light emitting pixel drivers EPD of the circuit layer 120 and a second power ELVSS.

For example, an anode electrode of the light emitting element LE may be electrically connected to the light emitting pixel driver EPD, and the second power ELVSS having a lower voltage level than a first power ELVDD may be applied to a cathode electrode of the light emitting element LE.

A capacitor Cel connected in parallel with the light emitting element LE represents parasitic capacitance between the anode electrode and the cathode electrode.

The circuit layer 120 may include a first power line VDL that transmits the first power ELVDD, a first initialization voltage line VGIL that transmits a first initialization voltage VGINT, and a second initialization voltage line VAIL that transmits a second initialization voltage VAINT.

The circuit layer 120 may further include a scan write line GWL that transmits a scan write signal GW, a scan initialization line GIL that transmits a scan initialization signal GI, an emission control line ECL that transmits an emission control signal EC, and a data line DL that transmits a data signal Vdata.

A light emitting pixel driver EPD of the circuit layer 120 may include one first transistor T1 that generates a driving current for driving the light emitting element LE, two or more transistors T2 to T7 electrically connected to the first transistor T1, and at least one capacitor PC1. In this case, the transistors T1 to T7 may be electrically connected to the light emitting element LE.

The first transistor T1 may be disposed between a first node N1 and a second node N2.

A first electrode (e.g., a source electrode) of the first transistor T1 may be electrically connected to a first node N1, and may be electrically connected to the first power line VDL through the fifth transistor T5.

A second electrode (e.g., a drain electrode) of the first transistor T1 may be electrically connected to a second node N2, and may be electrically connected to an anode electrode of the light emitting element LE through the sixth transistor T6.

A gate electrode of the first transistor T1 may be electrically connected to a third node N3.

The second transistor T2 may be electrically connected between the data line DL and the first node N1.

For example, the first electrode of the first transistor T1 may be electrically connected to the data line DL through the second transistor T2.

The second transistor T2 may be turned on by the scan write signal GW of the scan write line GWL.

The first capacitor PC1 may be electrically connected between the third node N3 and the first power line VDL. In this case, an end of the first capacitor PC1 may be electrically connected to the first power, and another end of the first capacitor PC1 may be electrically connected to the third node N3.

Accordingly, a potential of the gate electrode of the first transistor T1 may be maintained at a voltage charged in the first power line VDL.

In case that the data signal Vdata of the data line DL is transmitted to the first electrode of the first transistor T1 through a turned-on second transistor T2, a voltage difference between the gate electrode of the first transistor T1 and the first electrode of the first transistor T1 may be a difference voltage between the first power ELVDD and the data signal Vdata.

In this case, in case that the voltage difference between the gate electrode of the first transistor T1 and the first electrode of the first transistor T1 (e.g., a gate-source voltage difference) is substantially equal to a threshold voltage or more than the threshold voltage, the first transistor T1 may be turned on, thereby generating a drain-source current of the first transistor T1 corresponding to the data signal Vdata.

Subsequently, in case that the fifth transistor T5 and the sixth transistor T6 are turned on, the first transistor T1 may be electrically connected in series with the light emitting element LE between the first power ELVDD and a second power ELVSS. Accordingly, the drain-source current of the first transistor T1 corresponding to the data signal Vdata may be supplied as a driving current of the light emitting element LE.

Accordingly, the light emitting element LE may emit light with luminance corresponding to the data signal Vdata.

The third transistor T3 may be disposed between the second node N2 and the third node N3. For example, the third transistor T3 may be electrically connected between the gate electrode of the first transistor T1 and the second electrode (e.g., the drain electrode) of the first transistor T1.

The third transistor T3 may include multiple sub-transistors electrically connected in series. As an example, the third transistor T3 may include a first sub-transistor T31 and a second sub-transistor T32 electrically connected in series with the first sub-transistor T31.

A first electrode of the first sub-transistor T31 may be electrically connected to the gate electrode of the first transistor T1, a second electrode of the first sub-transistor T31 may be electrically connected to a first electrode of the second sub-transistor T32, and a second electrode of the second sub-transistor T32 may be electrically connected to the second electrode (e.g., the drain electrode) of the first transistor T1.

In this case, the potential of the gate electrode of the first transistor T1 may be prevented from being changed due to a leakage current caused by a third transistor T3 that is not turned on.

The first sub-transistor T31 and the second sub-transistor T32 may be turned on by the scan write signal GW of the scan write line GWL.

In case that the first sub-transistor T31 and the second sub-transistor T32 are turned on, the voltage difference between the second node N2 and the third node N3 may be initialized.

The fourth transistor T4 may be electrically connected between the third node N3 and the first initialization voltage line VGIL. For example, the fourth transistor T4 may be electrically connected between the gate electrode of the first transistor T1 and the first initialization voltage line VGIL.

The fourth transistor T4 may include multiple sub-transistors electrically connected in series. As an example, the fourth transistor T4 may include a third sub-transistor T41 and a fourth sub-transistor T42 electrically connected in series with the third sub-transistor T41.

A first electrode of the third sub-transistor T41 may be electrically connected to the gate electrode of the first transistor T1, a second electrode of the third sub-transistor T41 may be electrically connected to a first electrode of the fourth sub-transistor T42, and a second electrode of the fourth sub-transistor T42 may be electrically connected to the first initialization voltage line VGIL.

In this case, the potential of the gate electrode of the first transistor T1 may be prevented from being changed due to a leakage current caused by a fourth transistor T4 that is not turned on.

The third sub-transistor T41 and the fourth sub-transistor T42 may be turned on by the scan initialization signal GI of the scan initialization line GIL.

In case that the third sub-transistor T41 and the fourth sub-transistor T42 are turned on, the potential of the third node N3 may be initialized to the first initialization voltage VGINT.

The fifth transistor T5 may be disposed between the first node N1 and the first power line VDL. In this case, the fifth transistor T5 may be electrically connected between the first node N1 and the first power line VDL.

The sixth transistor T6 may be disposed between the second node N2 and a fourth node N4. In this case, the sixth transistor T6 may be electrically connected between the second node N2 and the fourth node N4.

The fourth node N4 may be electrically connected to the anode electrode of the light emitting element LE.

The fifth transistor T5 and the sixth transistor T6 may be turned on by the emission control signal EC of the emission control line ECL.

The seventh transistor T7 may be disposed between the fourth node N4 and the second initialization voltage line VAIL. In this case, the seventh transistor T7 may be electrically connected between the fourth node N4 and the second initialization voltage line VAIL.

The seventh transistor T7 may be turned on by the gate control signal GC of the gate control line GCL.

A potential of the fourth node N4 may be initialized to the second initialization voltage VAINT through the turned-on seventh transistor T7.

According to embodiments, the first to seventh transistors T1 to T7 may be provided as P-type MOSFETs. As another example, the third transistor T3 and the fourth transistor T4 among the first to seventh transistors T1 to T7 may be provided as N-type MOSFETs rather than P-type MOSFETs.

FIG. 6 is a schematic cross-sectional view illustrating first and sixth transistors and a light emitting element of FIG. 5.

Referring to FIG. 6, the display device 100 according to embodiments may include a substrate 110, a circuit layer 120 disposed on the substrate 110, an element layer 130 disposed on the circuit layer 120, and a sealing layer 140 disposed on the element layer 130.

The display device 100 according to embodiments may further include a touch sensor layer 160 disposed on the sealing layer 140 and a cover window 150 disposed on the touch sensor layer 160. The display device 100 may further include a polarizing layer disposed between the touch sensor layer 160 and the cover window 150.

According to embodiments, the circuit layer 120 may include an interlayer insulating layer 124 disposed on the substrate 110, first source drain conductive layers SDCDL1 (ANCE1) disposed on the interlayer insulating layer 124, a first planarization layer 125 covering the first source and drain conductive layers SDCDL1 (ANCE1), second source drain conductive layers SDCDL2 (ANCE2) disposed on the first planarization layer 125, and a second planarization layer 126 covering the second source drain conductive layers SDCDL2 (ANCE2).

The circuit layer 120 may further include semiconductor layers CH1, E11, E21, CH6, E16, and E26 disposed on the substrate 110, a first gate insulating layer 122 covering the semiconductor layers CH1, E11, E21, CH6, E16, and E26, first gate conductive layers G1 and G6 disposed on the first gate insulating layer 122, a second gate insulating layer 123 covering the first gate conductive layers G1 and G6, and second gate conductive layers CAE disposed on the second gate insulating layer 123.

The interlayer insulating layer 124 may be disposed on the second gate insulating layer 123 and may cover the second gate conductive layers CAE.

The circuit layer 120 may further include a buffer layer 121 disposed on the substrate 110.

In this case, the semiconductor layers CH1, E11, E21, CH6, E16, and E26 may be disposed on the buffer layer 121.

According to embodiments, each of the light emitting pixel drivers EPD may include a first transistor T1, and second to seventh transistors (T2 to T7 in FIG. 5) and at least one capacitor (PC1 in FIG. 5) electrically connected to the first transistor T1 or the light emitting element (LE in FIG. 5).

FIG. 6 illustrates the first transistor T1, the sixth transistor T6, and the light emitting element LE of the light emitting pixel driver EPD of FIG. 5.

The semiconductor layers disposed on the buffer layer 121 may include channel portions CH1 and CH6, first electrode portions E11 and E16, and second electrode portions E21 and E26 of each of the first to seventh transistors T1 to T7.

In each of the first transistor T1 and the sixth transistor T6, the first electrode portions E11 and E16 may be electrically connected to one end of the channel portions CHI and CH6, and the second electrode portions E21 and E26 may be electrically connected to the other ends of the channel portions CH1 and CH6.

The second electrode portion E21 of the first transistor T1 may be electrically connected to the first electrode portion E16 of the sixth transistor T6.

The first gate conductive layers disposed on the first gate insulating layer 122 may include gate electrodes G1 and G6 of each of the first to seventh transistors T1 to T7.

In each of the first transistor T1 and the sixth transistor T6, the gate electrodes G1 and G6 may overlap the channel portions CH1 and CH6.

Since the second transistor (T2 in FIG. 5), the first sub-transistor (T31 in FIG. 5), the second sub-transistor (T32 in FIG. 5), the third sub-transistor (T41 in FIG. 5), the fourth sub-transistor (T42 in FIG. 5), the fifth transistor (T5 in FIG. 5), and the seventh transistor (T7 in FIG. 5) of the light emitting pixel driver EPD are provided as the same P-type MOSFET as the first transistor T1 and the sixth transistor T6, the repeated descriptions will be omitted below.

The second gate conductive layers disposed on the second gate insulating layer 123 may include a capacitor electrode CAE.

The capacitor electrode CAE may overlap the gate electrode G1 of the first transistor T1.

Accordingly, a first pixel capacitor (PC1 in FIG. 5) may be provided by an overlapping area between the capacitor electrode CAE and the gate electrode G1 of the first transistor T1.

The first source drain conductive layer disposed on the interlayer insulating layer 124 may include a first anode connection electrode ANCE1.

The first anode connection electrode ANCE1 may be electrically connected to the second electrode portion E26 of the sixth transistor T6 through a first anode connection hole ANCH1 penetrating the first gate insulating layer 122, the second gate insulating layer 123, and the interlayer insulating layer 124.

The second source drain conductive layer disposed on the first planarization layer 125 may include a second anode connection electrode ANCE2.

The second anode connection electrode ANCE2 may be electrically connected to the first anode connection electrode ANCE1 through a second anode connection hole ANCH2 penetrating the first planarization layer 125.

The anode electrode 131 of the element layer 130 may be disposed on the second planarization layer 126, and may be electrically connected to the second anode connection electrode ANCE2 through a third anode connection hole ANCH3 penetrating the second planarization layer 126.

As a result, the anode electrode 131 may be electrically connected to the second electrode portion E26 of the sixth transistor T6 through the first anode connection electrode ANCE1 and the second anode connection electrode ANCE2.

The element layer 130 disposed on the circuit layer 120 may include light emitting elements LE disposed in the light emitting areas EA1, EA2, and EA3, respectively.

Each of the light emitting elements LE may include a structure in which the light emitting layer 133 is disposed between the anode electrode 131 and the cathode electrode 134 that face each other.

According to embodiments, the element layer 130 may include anode electrodes 131 disposed in the light emitting areas EA and partially disposed in the non-light emitting area NEA, a pixel defining layer 132 disposed in the non-light emitting area NEA and covering a portion of the anode electrode 131, a spacer layer 132′ disposed on a portion of the pixel defining layer 132, light emitting layers 133 each disposed on the anode electrodes 131, and a cathode electrode 134 disposed on the light emitting layers 133, the pixel defining layer 132, and the spacer layer 132′.

Each of the light emitting elements LE may further include first common layers 135 disposed between the anode electrodes 131 and the light emitting layers 133, and a second common layer 136 disposed between the light emitting layers 133 and the cathode electrode 134.

According to embodiments, the element layer 130 may further include a separation groove SPG disposed around each of the light emitting areas EA and formed concavely in the pixel defining layer 132.

The second common layer 136 may not be disposed only in the light emitting areas EA of the display area DA, but also may be disposed in the non-light emitting area NEA. In this case, the second common layer 136 may be entirely disposed in the display area DA.

As a result, the second common layer 136 may be disposed not only on the light emitting layers 133, but also on the pixel defining layer 132 and the spacer layer 132′.

According to embodiments, a portion of the second common layer 136 disposed on the pixel defining layer 132 may be disposed to have a relatively thin thickness on a side surface of the separation groove SPG. As an example, as the second common layer 136 is disposed on the side surface of the separation groove SPG with a thickness which is sufficiently thin to block a current flow through the second common layer 136, the common layer 136 may be disconnected. As another example, in a process of disposing the second common layer 136, as the amount of material flowing into the separation groove SPG becomes relatively small, the second common layer 136 may also be separated in the separation groove.

For example, the second common layer 136 may be disconnected or separated in the separation groove SPG.

In this case, a leakage current through the second common layer 136 may be prevented between the light emitting areas EA adjacent to each other. Accordingly, a defect in which the light emitting element LE to which no driving current is applied emits light due to the leakage current transferred from the light emitting element in the adjacent light emitting area EA may be prevented. Therefore, an image quality of the display device 100 may be improved.

The sealing layer 140 may be disposed on the circuit layer 120 to cover the element layer 130.

The sealing layer 140 may be used to block permeation of oxygen or moisture into the element layer 130 and to relieve electrical or physical shock to the circuit layer 120 and the element layer 130.

The sealing layer 140 may include a first sealing layer 141 disposed on the element layer 130 and including an inorganic insulating material, a second sealing layer 142 disposed on the first sealing layer 141, overlapping the element layer 130 of the display area DA, and including an organic insulating material, and a third sealing layer 143 disposed on the first sealing layer 141, covering the second sealing layer 142, and including an inorganic insulating material.

The touch sensor layer 160 may be disposed on the sealing layer 140. The touch sensor layer 160 may include touch electrodes for detecting a signal that varies depending on a touch of a person or object and sensing a point in the main area MA where the touch of the person or object occurred.

The cover window 150 may be disposed on the touch sensor layer 160.

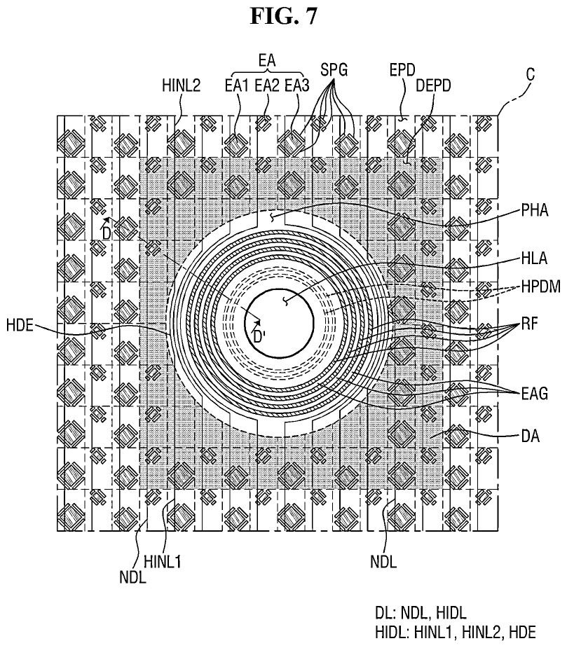

FIG. 7 is a schematic layout view illustrating portion C of FIG. 2.

Referring to FIG. 7, the substrate (110 in FIG. 3) of the display device 100 according to embodiments may include a hole area HLA surrounded by the display area DA, and a hole peripheral area PHA disposed between the hole area HLA and the display area DA.

The light transmitting hole (TRH in FIG. 3) penetrating through the substrate (110 in FIG. 3), the circuit layer (120 in FIG. 3), the element layer (130 in FIG. 3), and the sealing layer (140 in FIG. 3) may be disposed in the hole area HLA.

According to embodiments, the circuit layer (120 in FIG. 3) may include roof portions RF disposed in the hole peripheral area PHA and sequentially surrounding the hole area HLA, and one or more sealing auxiliary grooves EAG positioned between the adjacent roof portions RF.

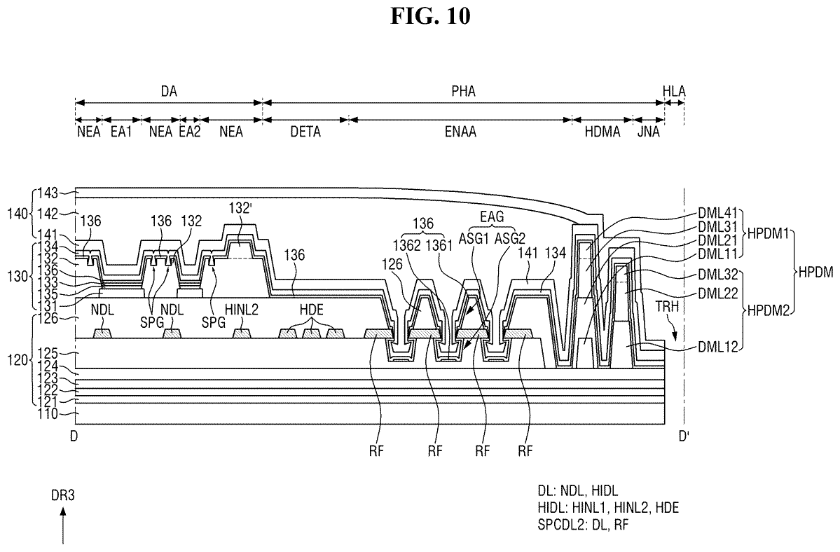

As described above with reference to FIG. 6, as the second common layer (136 in FIG. 6) of the element layer (130 in FIG. 10) is disposed in the display area DA, the second common layer 136 may also be disposed in the hole peripheral area PHA surrounded by the display area DA.

The roof portions RF and one or more sealing auxiliary grooves EAG disposed in the hole peripheral area PHA may be used to separate the second common layer (136 in FIG. 6) disposed in the hole peripheral area PHA. As a result, permeation of oxygen or moisture through the light transmitting hole (TRH in FIG. 3) in the hole area HLA and the second common layer (136 in FIG. 6) in the hole peripheral area PHA may be delayed.

The display device 100 according to embodiments may further include one or more hole peripheral dams HPDM disposed between the roof portions RF of the hole peripheral area PHA and the hole area HLA and surrounding the hole area HLA.

The one or more hole peripheral dams HPDM may be a barrier that blocks the second sealing layer (142 in FIG. 6) of the sealing layer (140 in FIG. 10) including the organic material from diffusing into the hole area HLA.

According to embodiments, the element layer (130 in FIG. 6) of the display device 100 may further include a separation groove SPG disposed around each of the light emitting areas EA in the non-light emitting area (NEA in FIG. 6) of the display area DA and formed concavely in the pixel defining layer 132.

Since the separation groove SPG may disconnect the second common layer (136 in FIG. 6) between adjacent light emitting areas EA, it may not completely surround each light emitting area EA.

As an example, the separation groove SPG may be disposed to be parallel to each side of an edge of each of the light emitting areas EA. For example, the separation groove SPG may be disposed to be parallel to only each side of the edge of each of the light emitting areas EA, and may not be disposed around each vertex.

In other words, in case that each of the light emitting areas EA has a square shape, the edge of each light emitting area EA may be adjacent to four separation grooves SPG.

According to embodiments, the circuit layer (120 in FIG. 3) may include light emitting pixel drivers EPD arranged in the first direction DR1 and the second direction DR2 in the display area DA, and data lines DL that extend in the second direction DR2 and transmit the data signals (Vdata in FIG. 5) to the light emitting pixel drivers EPD.

As the light emitting pixel drivers EPD are arranged on both sides of the hole peripheral area PHA in the second direction DR2, the data lines DL may include hole intersecting data lines HIDL that intersect the hole area HLA or the hole peripheral area PHA.

For example, the data lines DL may include hole intersecting data lines HIDL that intersect the hole area HLA or the hole peripheral area PHA, and normal data lines NDL except for the hole intersecting data lines HIDL.

Each of the hole interesting data lines HIDL may include a first hole separation line HINL1 facing one side of the hole peripheral area PHA in the second direction DR2, a second hole separation line HINL2 facing the other side of the hole peripheral area PHA in the second direction DR2, and a hole bypass line HDE disposed in the hole peripheral area PHA and electrically connecting the first hole separation line HINL1 to the second hole separation line HINL2.

The hole bypass line HDE may be disposed between sealing auxiliary portions ENAS and the display area DA, and may be in the form of a curved arc extending parallel to a periphery of the sealing auxiliary portions ENAS.

Each of the normal data lines NDL may be provided in the form that does not intersect the hole area HLA and the hole peripheral area PHA and does not include a curved hole bypass line HDE disposed in the hole peripheral area PHA.

According to embodiments, the circuit layer 120 may further include dummy light emitting pixel drivers DEPD disposed closest to the hole peripheral area PHA.

The dummy light emitting pixel drivers DEPD may have the same structure as the light emitting pixel drivers EPD except that the dummy light emitting pixel drivers DEPD may not be electrically connected to the light emitting elements (LE in FIG. 5) of the element layer (130 in FIG. 3).

In the process of disposing the light transmitting hole (TRH in FIG. 3) in the hole area HLA, since physical or chemical shock may be buffered by the dummy light emitting pixel drivers DEPD, the possibility of damage to the light emitting pixel drivers EPDs in the process of disposing the light transmitting hole (TRH in FIG. 3) may be reduced.

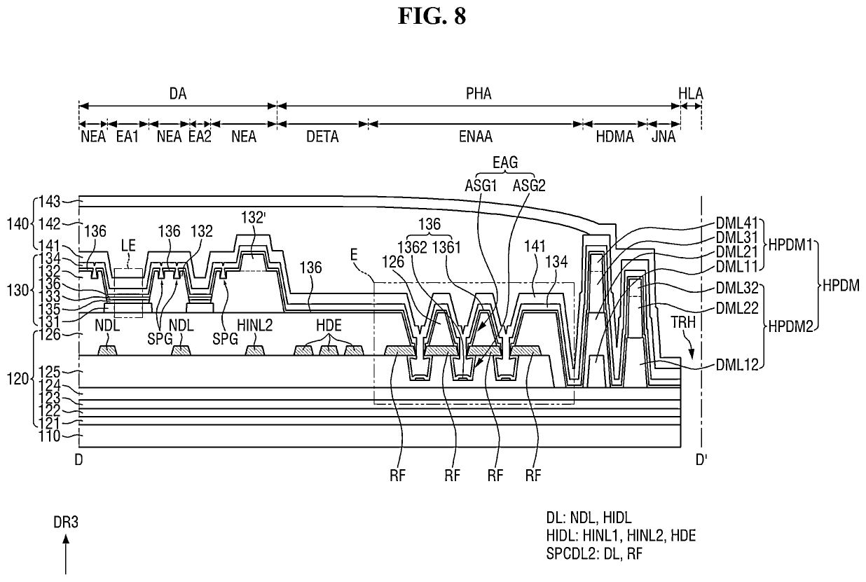

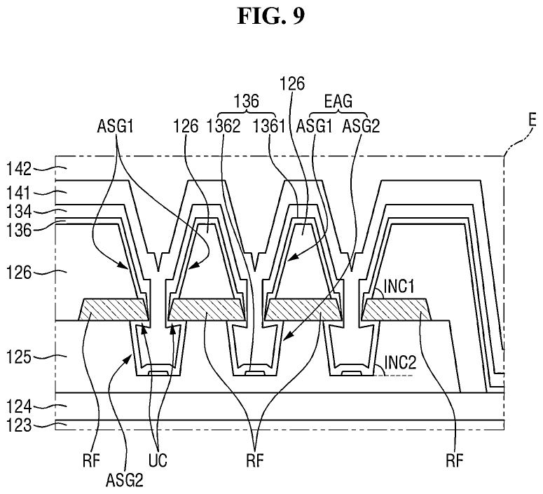

FIG. 8 is a schematic cross-sectional view taken along line D-D′ of FIG. 7 according to an embodiment. FIG. 9 is a schematic enlarged view illustrating portion D of FIG. 8.

Referring to FIG. 8, the circuit layer 120 of the display device 100 according to embodiments may include an interlayer insulating layer 124 disposed on the substrate 110, a first planarization layer 125 disposed on the interlayer insulating layer 124, two or more roof portions RF disposed in the hole peripheral area PHA disposed on the first planarization layer 125 and sequentially surrounding the hole area HLA, a second planarization layer 126 disposed on the first planarization layer 125 and covering the two or more roof portions RF, and one or more sealing auxiliary grooves EAG positioned between the two or more roof portions RF.

As an example, two or more roof portions RF and one or more sealing auxiliary grooves EAG may be disposed in a sealing auxiliary area ENAA of the hole peripheral area PHA spaced apart from each of the hole area HLA and display area DA.

Each of the one or more sealing auxiliary grooves EAG may include a first auxiliary groove ASG1 penetrating through the second planarization layer 126, and a second auxiliary groove ASG2 formed concavely in the first planarization layer 125.

As illustrated in FIG. 9, according to embodiments, a slope INC2 of a side surface of the second auxiliary groove ASG2 may be steeper than a slope INC1 of a side surface of the first auxiliary groove ASG1.

In a direction in which the two or more roof portions RF face each other (e.g., a direction between the hole area HLA and the display area DA), at least a portion of an edge of each of the two or more roof portions RF may protrude more than the second auxiliary groove ASG2 of the one or more sealing auxiliary grooves EAG.

For example, in the direction in which the two or more roof portions RF face each other, a width of a spaced area between the roof portions RF may be smaller than a width of the second auxiliary groove ASG2 of the one or more sealing auxiliary grooves EAG.

As a result, in the spaced area between the two or more roof portions RF, an undercut structure UC in which the edges of the two or more roof portions RF protrude more than the second auxiliary groove ASG2 may be formed.

Since the second common layer 136 and the cathode electrode 134 of the element layer 130 are entirely disposed in the display area DA, the second common layer 136 and the cathode electrode 134 may also be disposed in the hole peripheral area PHA surrounded by the display area DA.

The second common layer 136 may be disposed on the light emitting layers 133, the pixel defining layer 132, and a spacer layer 132′ in the display area DA.

The pixel defining layer 132 may be disposed in the display area DA and may not extend to the hole peripheral area PHA. Accordingly, the second common layer 136 may be disposed on the second planarization layer 126 in the hole peripheral area PHA.

Since the second common layer 136 includes an organic material that is relatively vulnerable to permeation by oxygen or moisture, oxygen or moisture may readily flow into the circuit layer 120 and the element layer 130 of the display area DA through the light transmitting hole TRH in the hole area HLA and the second common layer 136 in the hole peripheral area PHA.

As illustrated in FIG. 8, the circuit layer 120 of the display device 100 according to embodiments may include the roof portions RF and one or more sealing auxiliary grooves EAG disposed in the hole peripheral area PHA to prevent or delay such permeation.

As the one or more sealing auxiliary grooves EAG may include a second auxiliary groove ASG2 which has a greater width than a gap between the roof portions RF, an undercut structure UC may be formed between the roof portions RF and the second auxiliary groove ASG2.

Accordingly, in the process of disposing the second common layer 136, it is difficult for the organic material to be stacked in a form that extends from the side surface of the roof portions RF to the side surface of the second auxiliary groove ASG2 due to the roof portions RF protruding more than the second auxiliary groove ASG2. For example, a portion of the second common layer 136 disposed in the hole peripheral area PHA may be separated by the undercut structure UC. In this case, the second common layer 136 may be disconnected by the undercut structure UC.

In other words, a portion of the second common layer 136 disposed in the hole peripheral area PHA may include two or more first division portions 1361 disposed on the second planarization layer 126 and overlapping the two or more roof portions RF, and one or more second division portions 1362 disposed in the second auxiliary groove ASG2 of the one or more sealing auxiliary grooves EAG and spaced apart from the two or more first division portions 1361.

Although the display device 100 according to embodiments includes the light transmitting hole TRH surrounded by the display area DA and the second common layer 136 disposed in the hole peripheral area PHA, the second common layer 136 of the hole peripheral area PHA may be separated by the two or more roof portions RF and the one or more sealing auxiliary grooves EAG disposed in the hole peripheral area PHA. As a result, permeation of oxygen or moisture through the second common layer 136 in the hole peripheral area PHA may be delayed. Since a rapid decrease in the lifespan of the display device 100 due to the light transmitting hole TRH may be prevented, the overall lifespan of the display device 100 may be improved accordingly.

As illustrated in FIG. 8, according to embodiments, the roof portions RF disposed in the hole peripheral area PHA on the first planarization layer 125 may be formed in the same layer as the second source drain conductive layer SDCDL2 disposed in the display area DA on the first planarization layer 125.

The second source drain conductive layer SDCDL2 may include the data lines (DL in FIG. 7).

The data lines (DL in FIG. 7) may include hole intersecting data lines (HIDL in FIG. 7) and normal data lines NDL. The hole intersecting data line (HIDL in FIG. 7) may include a first hole separation line (HINL1 in FIG. 7), a second hole separation line (HINL2 in FIG. 7), and a hole bypass line HDE.

The hole bypass lines HDE of the hole intersecting data lines (HIDL in FIG. 7) may be disposed in a bypass area DETA disposed between the non-light emitting area NEA of the display area DA and the sealing auxiliary area ENAA of the hole peripheral area PHA.

According to embodiments, the display device 100 may further include one or more hole peripheral dams HPDM disposed between two or more roof portions RF of the hole peripheral area PHA and the hole area HLA and surrounding the hole area HLA. For example, one or more hole peripheral dams HPDM may be sequentially disposed in the hole peripheral dam area HDMA in the hole peripheral area PHA between the sealing auxiliary area ENAA and the hole area HLA.

Each of the one or more hole peripheral dams HPDM may include two or more dam layers DML11, DML12, DML21, DML22, DML31, DML32, and DML41.

Each of the dam layers DML11, DML12, DML21, DML22, DML31, DML32, DML2, and DML41 may be disposed on the same layer as one of the first planarization layer 125, the second planarization layer 126, the pixel defining layer 132, and the spacer layer 132′.

As an example, one or more hole peripheral dams HPDM may include a first hole peripheral dam HPDM1 adjacent to the sealing auxiliary area ENAA and a second hole peripheral dam HPDM2 disposed between the first hole peripheral dam HPDM1 and the hole area HLA.

The first hole peripheral dam HPDM1 may include a first dam layer DML11 disposed on the same layer as the first planarization layer 125, a second dam layer DML21 disposed on the same layer as the second planarization layer 126, a third dam layer DML31 disposed on the same layer as the pixel defining layer 132, and a fourth dam layer DML41 disposed on the same layer as the spacer layer 132′

The second hole peripheral dam HPDM2 may include a first dam layer DML12 disposed on the same layer as the second planarization layer 126, a second dam layer DML22 disposed on the same layer as the pixel defining layer 132, and a third dam layer DML32 disposed on the same layer as the spacer layer 132′.

The sealing layer 140 of the display device 100 according to embodiments may include a first sealing layer 141 disposed on the element layer 130, a second sealing layer 142 disposed on the first sealing layer 141 and overlapping the display area DA, and a third sealing layer 143 disposed on the second sealing layer 142 and covering the second sealing layer 142.

The second sealing layer 142 may extend to one or more hole peripheral dams HPDM and include an organic insulating material spaced apart from the hole area HLA.

Each of the first sealing layer 141 and the third sealing layer 143 may include an inorganic insulating material.

Since the second sealing layer 142 extends to the one or more hole peripheral dams HPDM, the first sealing layer 141 and the third sealing layer 143 may be in contact with each other in a junction area JNA between the hole area HLA and one or more hole peripheral dams HPDM of the hole peripheral area PHA.

Since the second sealing layer 142 extends to the one or more hole peripheral dams HPDM, and the sealing auxiliary area ENAA is disposed between the hole peripheral dam area HDMA and the display area DA, the roof portions RF and the one or more sealing auxiliary grooves EAG disposed in the sealing auxiliary area ENAA may overlap the second sealing layer

In this case, an undercut structure UC formed by the roof portions RF and the one or more sealing auxiliary grooves EAG may be protected from physical shock by the second sealing layer 142.

The circuit layer 120 may further include a buffer layer 121 disposed on the substrate 110, a first gate insulating layer 122 disposed on the buffer layer 121, and a second gate insulating layer 123 disposed on the first gate insulating layer 122. An interlayer insulating layer 124 may be disposed on the second gate insulating layer 123.

Each of the buffer layer 121, the first gate insulating layer 122, the second gate insulating layer 123, and the interlayer insulating layer 124 may include an inorganic insulating material.

Each of the second common layer 136 and the cathode electrode 134 may be entirely disposed in the display area DA.

Each of the first sealing layer 141 and the third sealing layer 143 may include an inorganic insulating material and may be entirely disposed in the display area DA.

Accordingly, the light transmitting hole TRH of the hole area HLA may penetrate through the third sealing layer 143, the first sealing layer 141, the cathode electrode 134, the second common layer 136, the interlayer insulating layer 124, the second gate insulating layer 123, the first gate insulating layer 122, the buffer layer 121, and the substrate 110.

FIG. 10 is a schematic cross-sectional view taken along line D-D′ of FIG. 7 according to an embodiment.

Since the display device 100 according to an embodiment illustrated in FIG. 10 is substantially the same as the display device 100 according to the embodiments illustrated in FIGS. 8 and 9, except that a gap between the two or more roof portions RF is sufficiently large so that the second sealing layer 142 is disposed in the second auxiliary groove ASG2 of the one or more sealing auxiliary grooves EAG, the repeated descriptions will be omitted below.

In this case, since the second auxiliary groove ASG2 may be protected by the second sealing layer 142, a damage to the second auxiliary groove ASG2 due to external physical shock applied during processes such as arrangement of the light transmitting hole TRH and transportation of the display device 100 may be prevented.

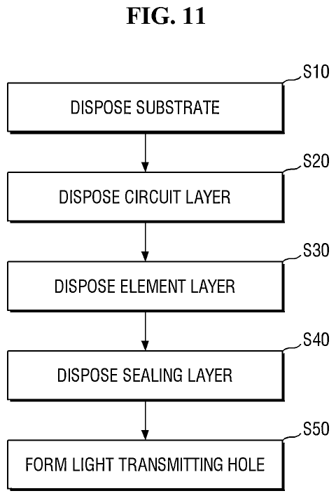

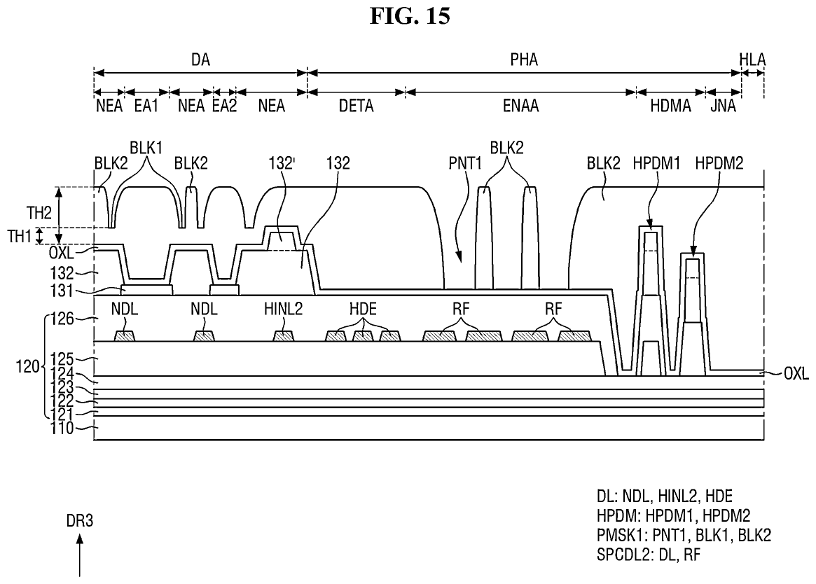

FIGS. 11, 12, 13, and 14 are schematic flowcharts illustrating a method for manufacturing a display device according to embodiments. FIGS. 15, 16, 17, 18, 19, 20, 21, 22, 23, 24 and 25 are process diagrams illustrating some of the steps of FIGS. 11, 12, 13, and 14.

Referring to FIG. 11, a method for manufacturing a display device 100 according to embodiments may include a step of preparing a substrate 110 (S10), a step of disposing a circuit layer 120 on the substrate 110 (S20), a step of disposing an element layer 130 on the circuit layer 120 (S30), a step of disposing a sealing layer 140 on the element layer 130 (S40), and a step of forming a light transmitting hole TRH penetrating the substrate 110, circuit layer 120, device layer 130, and sealing layer 140 in the hole area (HLA in FIG. 2) (S50)

In the preparing of the substrate 110 (S10), the substrate 110 may include a display area (DA in FIG. 2) in which light emitting areas (EA in FIG. 4) are arranged, a non-display area (NDA in FIG. 2) disposed around the display area DA, a hole area (HLA in FIG. 2) surrounded by the display area DA, and a hole peripheral area (PHA in FIG. 2) disposed between the display area DA and the hole area HLA.

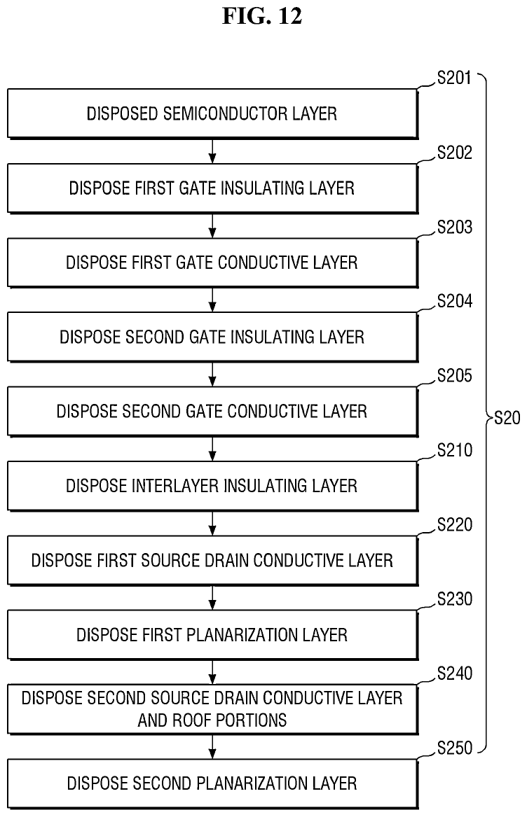

Referring to FIG. 12, the step of the disposing of the circuit layer 120 (S20) according to embodiments may include a step of disposing an interlayer insulating layer (124 in FIG. 8) on the substrate 110 (S210), a step of disposing a first source drain conductive layer (SDCDL1 in FIG. 6) in the display area DA on the interlayer insulating layer 124 (S220), a step of disposing a first planarization layer 125 covering the first source drain conductive layer SDCDL1 on the interlayer insulating layer 124 (S230), a step of disposing a second source drain conductive layer (SDCDL2 in FIGS. 6 and 8) of the display area DA and a roof portion (RF in FIG. 8) of the hole peripheral area PHA on the first planarization layer 125 (S240), and a step of disposing a second planarization layer 126 covering the second source drain conductive layer SDCDL2 and the roof portion RF on the first planarization layer 125 (S250).

The step of the disposing of the circuit layer 120 (S20) according to embodiments may further include, before the step of the disposing of the interlayer insulating layer 124 (S210), a step of disposing a semiconductor layer (CH1, E11, E21, CH6, E16, and E26 in FIG. 6) on the substrate 110 (S201), a step of disposing a first gate insulating layer (122 in FIGS. 6 and 8) covering the semiconductor layer (S202), disposing a first gate conductive layer (G1, G6 in FIG. 6) on the first gate insulating layer 122 (S203), a step of disposing a second gate insulating layer (123 in FIGS. 6 and 8) covering the first gate conductive layer (S204), and a step of disposing a second gate conductive layer (CAE in FIG. 6) on the second gate insulating layer 123 (S205).

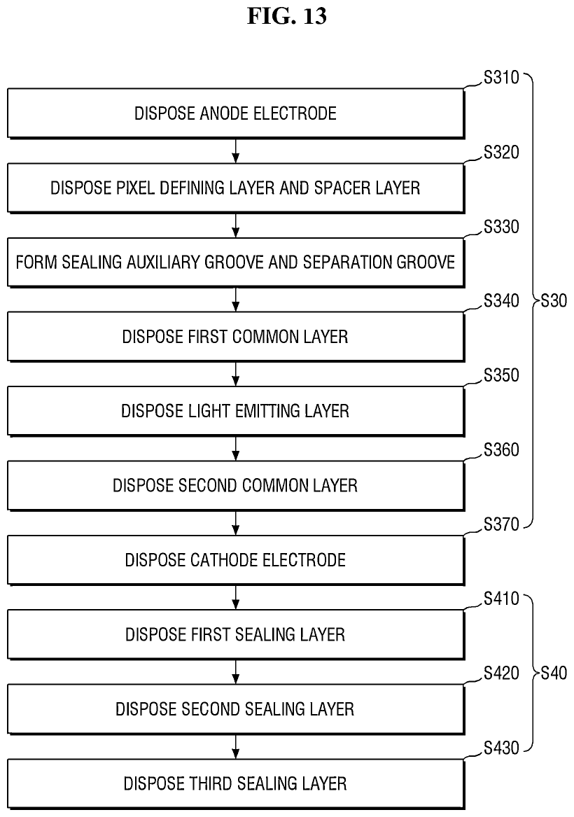

Referring to FIG. 13, the step of the disposing of the element layer 130 (S30) according to embodiments may include a step of disposing anode electrodes (131 in FIG. 6) of the light emitting areas EA on the second planarization layer 126 (S310), a step of disposing a pixel defining layer (132 in FIGS. 6 and 8) of the non-light emitting area disposed between the light emitting areas EA on the second planarization layer 126 and disposing a spacer layer (132′ in FIGS. 6 and 8) on a portion of the pixel defining layer 132 (S320), a step of forming a sealing auxiliary groove (EAG in FIG. 8) in the hole peripheral area PHA and a separation groove (SPG in FIGS. 6 and 8) in the display area DA (S330), a step of disposing first common layers (135 in FIG. 6) on the anode electrodes 131 (S340), disposing light emitting layers (133 in FIG. 6) on the first common layers 135 (S350), a step of disposing a second common layer (136 in FIGS. 6 and 8) covering the pixel defining layer 132, the spacer layer 132′, and the light emitting layer 133 in the display area DA (S360), and a step of disposing a cathode electrode (134 in FIGS. 6 and 8) on the second common layer 136 (S370).

The step of the disposing of the sealing layer 140 (S40) may include a step of disposing a first sealing layer (141 in FIG. 8) (S410), a step of disposing a second sealing layer (142 in FIG. 8) (S420), and a step of disposing a third sealing layer (143 in FIG. 8) (S430).

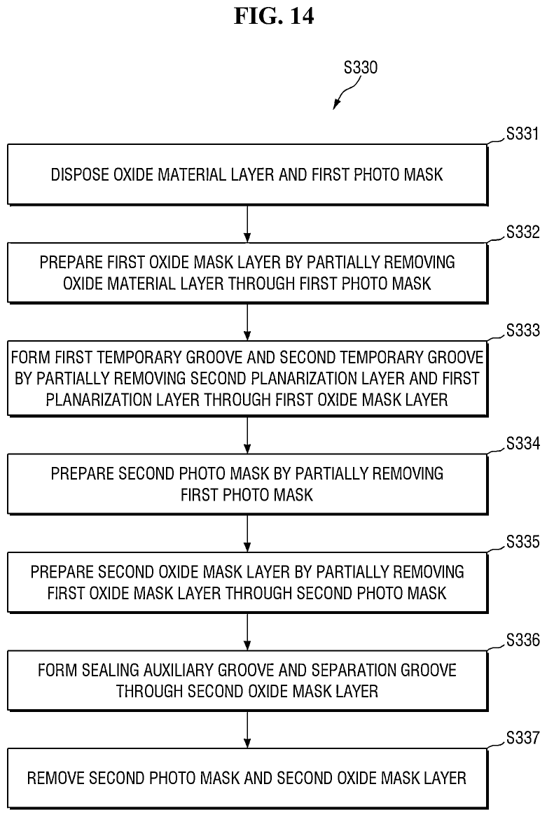

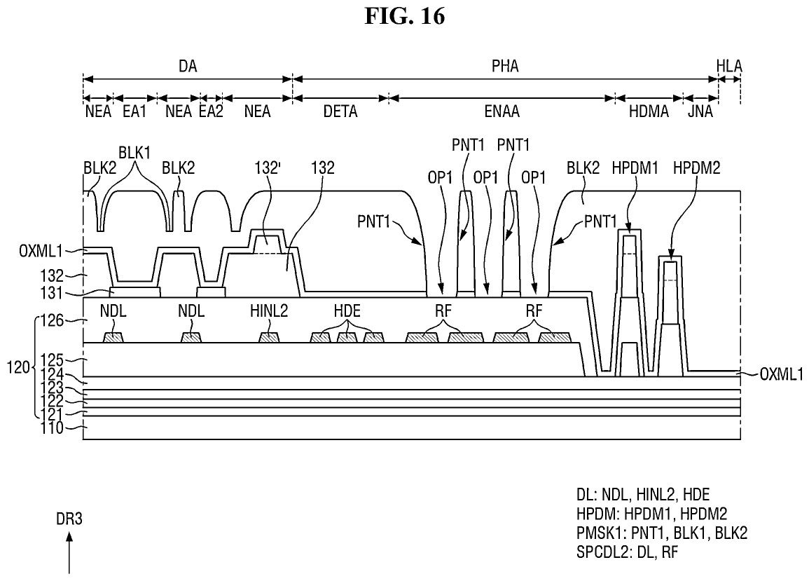

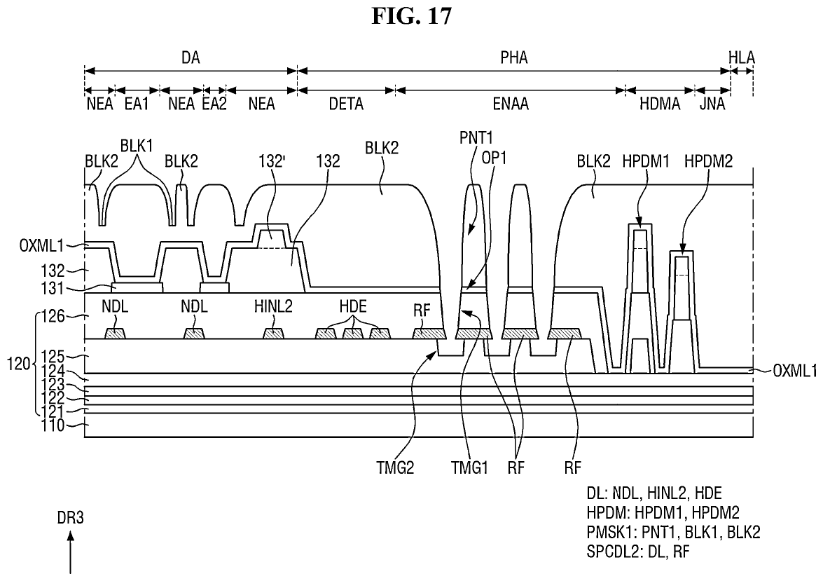

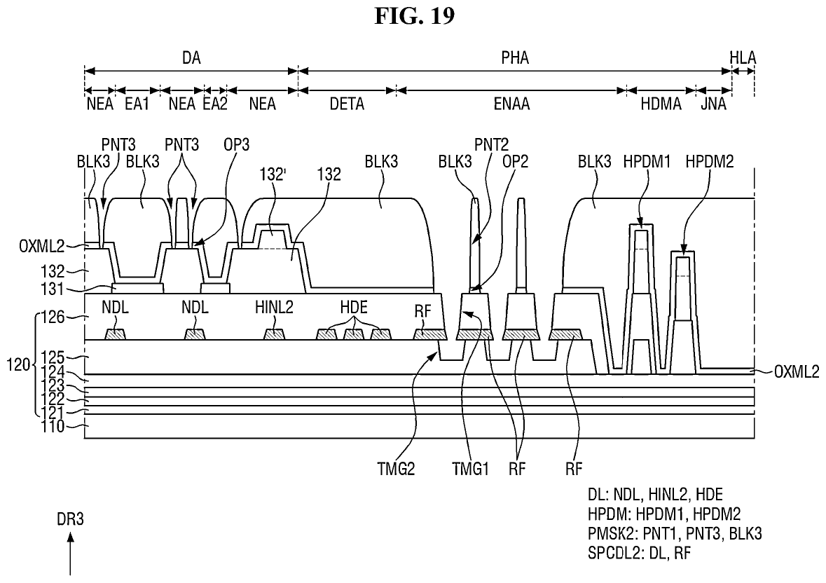

Referring to FIG. 14, the step of the forming of the sealing auxiliary groove (EAG in FIG. 8) in the hole peripheral area PHA and the separation groove (SPG in FIGS. 6 and 8) in the display area DA (S330) may include a step of disposing an oxide material layer (OXL in FIG. 15) covering the pixel defining layer 132 in the display area DA and the second planarization layer 126 in the hole peripheral area PHA and disposing a first photo mask (PMSK1 in FIG. 15) on the oxide material layer (OXL) (S331), a step of preparing a first oxide mask layer (OXML1 in FIG. 16) by partially removing the oxide material layer (OXL) through the first photo mask (PMSK1) (S332), a step of forming a first temporary groove (TMG1 in FIG. 17) penetrating through the second planarization layer 126 and a second temporary groove (TMG2 in FIG. 17) formed concavely in the first planarization layer 125 by partially removing the second planarization layer 126 and the first planarization layer 125 in the hole peripheral area PHA through the first oxide mask layer OXML1 (S333), a step of preparing a second photo mask PMSK2 by partially removing the first photo mask PMSK1 (S334), preparing a second oxide mask layer (OXML2 in FIG. 19) by partially removing the first oxide mask layer OXML1 through the second photo mask PMSK2 (S335), a step of forming a separation groove (SPG in FIG. 8) by partially removing the pixel defining layer 132 through the second oxide mask layer OXML2 and forming a sealing auxiliary groove (EAG in FIG. 8) by additionally removing the second planarization layer 126 and the first planarization layer 125 through the second oxide mask layer OXML2, the first temporary groove TMG1, and the second temporary groove TMG2 (S336), and a step of removing the second photo mask PMSK2 and the second oxide mask layer OXML2 (S337).

Referring to FIG. 15, in the step of the disposing of the oxide material layer OXL and the first photo mask PMSK1 (S331), the oxide material layer OXL may be disposed to cover the pixel defining layer 132 in the display area DA and the second planarization layer 126 in the hole peripheral area PHA by stacking an oxide material. Next, the first photo mask PMSK1 may be disposed by partially removing a photo mask material stacked on the oxide material layer OXL.

The oxide material layer OXL may be entirely disposed in the display area DA and the non-display area NDA of the substrate 110. The oxide material layer OXL may also be disposed in the hole peripheral area PHA and the hole area HLA surrounded by the display area DA. Accordingly, the oxide material layer OXL may further include the spacer layer 132′ in the display area DA, the hole peripheral dam HPDM in the hole peripheral area PHA, the interlayer insulating layer 124 around the hole peripheral dam HPDM, and the interlayer insulating layer 124 around the hole area HLA.

The first photo mask PMSK1 may include a first transmitting portion PNT1 exposing the oxide material layer OXL, a first blocking portion BLK1 having a first thickness TH1 in the third direction DR3, and a second blocking portion BLK2 having a second thickness TH2 greater than the first thickness TH1 in the third direction DR3.

The first transmitting portion PNT1 may overlap an area between the roof portions RF in the third direction DR3, which is disposed in the sealing auxiliary area ENAA of the hole peripheral area PHA.

The first photo mask PMSK1 may include one or more first transmitting portions PNT1 overlapping between adjacent ones of the roof portions RF.

The first blocking portion BLK1 may overlap a portion of the non-light emitting area NEA of the display area DA adjacent to each of the light emitting areas EA.

As an example, the first blocking portion BLK1 may overlap a portion of the non-light emitting area NEA adjacent to each side of an edge of each of the light emitting areas EA.

The second blocking portion BLK2 may be the remainder of the first photo mask PMSK1 excluding the first transmitting portion PNT1 and the first blocking portion BLK1.

Referring to FIG. 16, in the step of the preparing of the first oxide mask layer OXML1 (S332), the first oxide mask layer OXML1 including a first opening OP1 may be prepared by partially removing the oxide material layer (OXL in FIG. 15) through the first transmitting portion PNT1 of the first photo mask PMSK1.

The first opening OP1 may correspond to the first transmitting portion PNT1. For example, the first opening OP1 may be connected to the first transmitting portion PNT1 and may expose the second planarization layer 126 in the hole peripheral area PHA.

Referring to FIG. 17, in the step of the forming of the first temporary groove TMG1 and the second temporary groove TMG2 (S333), the first temporary groove TMG1 may be formed by partially removing a portion of the second planarization layer 126 exposed through the first opening OP1 of the first oxide mask layer OXML1.

The first temporary groove TMG1 may penetrate through the second planarization layer 126 and expose the first planarization layer 125.

Next, the second temporary groove TMG2 may be formed by partially removing a portion of the first planarization layer 125 exposed through the first temporary groove TMG1.

The second temporary groove TMG2 may not completely penetrate through the first planarization layer 125 and may be concavely formed in the first planarization layer 125.

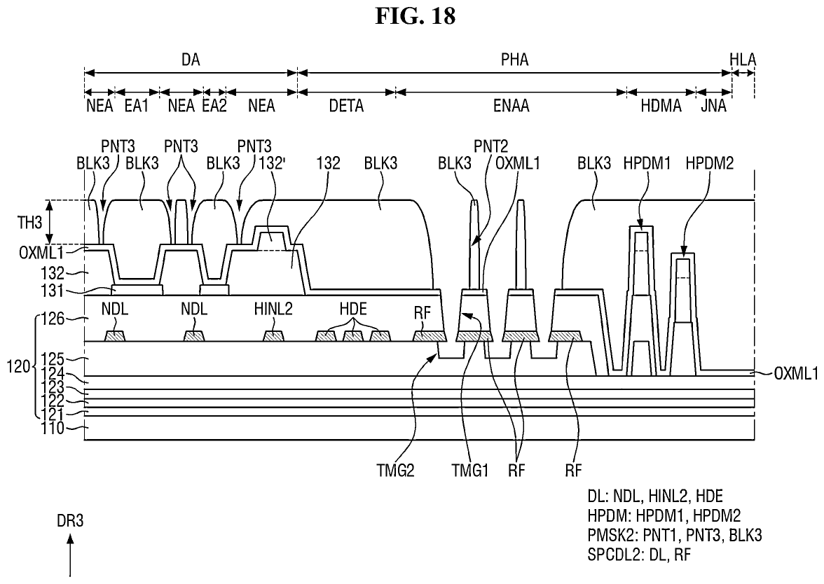

Referring to FIG. 18, in the step of the preparing of the second photo mask PMSK2 (S334), the second photo mask PMSK2 may be prepared by partially removing the first photo mask PMSK1.

As an example, the second photo mask PMSK2 may be prepared by performing an ashing process on the first photo mask PMSK1 until all of the first blocking portion BLK1 of the first thickness TH1 is removed.

The second photo mask PMSK2 may include a second transmitting portion PNT2 overlapping between the roof portions RF of the hole peripheral area PHA, a third transmitting portion PNT3 overlapping a portion of the non-light emitting area NEA of the display area DA adjacent to each of the light emitting areas EA, and a third blocking portion BLK3 having a third thickness TH3 smaller than the second thickness TH2.

The second transmitting portion PNT2 may be prepared by removing a portion of the second blocking portion BLK2 of the first photo mask PMSK2 around the first transmitting portion (PNT1 in FIG. 17).

For example, the second transmitting portion PNT2 may correspond to the first transmitting portion (PNT1 in FIG. 17) and may have a wider width than the first transmitting portion (PNT1 in FIG. 17).

Accordingly, a portion of the first oxide mask layer OXML1 around the first temporary groove TMG1 may be exposed without being covered by the second photo mask PMSK2.

The third transmitting portion PNT3 may be prepared by removing the first blocking portion (BLK1 in FIG. 17). For example, the third transmitting portion PNT3 may correspond to the first blocking portion (BLK1 in FIG. 17).

The third blocking portion BLK3 may be prepared as a residual portion of the second blocking portion (BLK2 in FIG. 17).

Referring to FIG. 19, in the step of the preparing of the second oxide mask layer OXML2 (S335), the second oxide mask layer OXML2 including a second opening OP2 and a third opening OP3 may be prepared by partially removing the first oxide mask layer OXML1 through the second transmitting portion PNT2 and the third transmitting portion PNT3 of the second photo mask PMSK2.

The second opening OP2 may correspond to the second transmitting portion PNT2. For example, the second opening OP2 may be connected to the second transmitting portion PNT2 and may expose the first temporary groove TMG1 and the second planarization layer 126 around the first temporary groove TMG1.

The third opening OP3 may correspond to the third transmitting portion PNT3. For example, the third opening OP3 may be connected to the third transmitting portion PNT3 and may expose the pixel defining layer 132 of the display area DA.

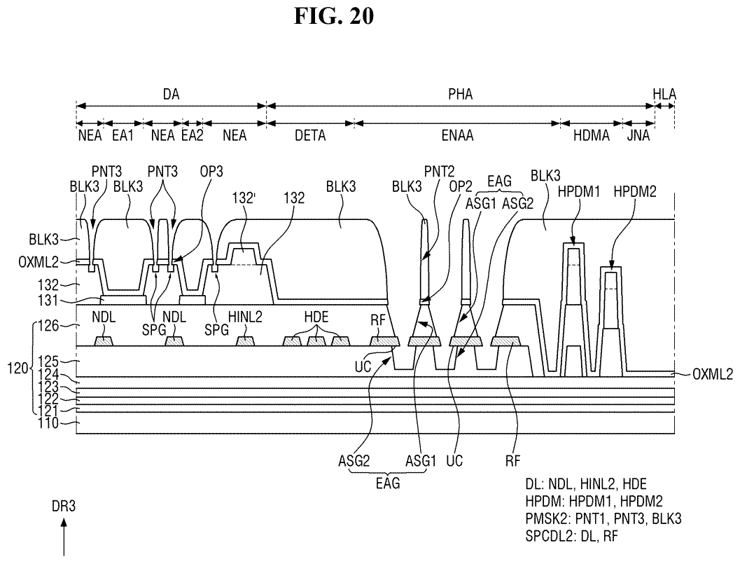

Referring to FIG. 20, in the step of the forming of the sealing auxiliary groove EAG (S336), the first auxiliary groove ASG1 may be prepared by removing a portion of the second planarization layer 126 around the first temporary groove TMG1 through the second opening OP2 of the second oxide mask layer OXML2. The second auxiliary groove ASG2 may be prepared by removing a portion of the first planarization layer 125 around the second temporary groove TMG2 through the second opening OP2 and the first auxiliary groove ASG1 of the second oxide mask layer OXML2.

A lower width of the first auxiliary groove ASG1, like a lower width of the first temporary groove TMG1, is limited by the gap between the roof portions RF, while due to the second opening OP2 which is wider than the first opening OP1, an upper width of the first auxiliary groove ASG1 becomes wider than an upper width of the first temporary groove TMG1. Accordingly, a slope of a side surface of the first auxiliary groove ASG1 may be smaller than a slope of a side surface of the first temporary groove TMG1.

The second auxiliary groove ASG2 may be prepared by additionally removing a portion around the second temporary groove TMG2 by an etching material introduced through the area between the first auxiliary groove ASG1 and the roof portions RF. Therefore, the second auxiliary groove ASG2 may be formed to have a greater depth than the second temporary groove TMG2 in the third direction DR3. Further, an upper width of the second auxiliary groove ASG2 is limited by the gap between the roof portions RF, while due to the additional etching process, a lower width of the second auxiliary groove ASG2 may be wider than a lower width of the second temporary groove TMG2. Accordingly, a slope of a side surface of the second auxiliary groove ASG2 may be steeper than a slope of a side surface of the second temporary groove TMG2.

In this case, the slope of the side surface of the second auxiliary groove ASG2 may be steeper than a slope of a side surface of the first auxiliary groove ASG1.

As a result, one or more sealing auxiliary grooves EAG including the first auxiliary groove ASG1 and the second auxiliary groove ASG2 may be prepared.

Due to an etch ratio between the first planarization layer 125 and the roof portions RF, at least a portion of the edge of each of the roof portions RF may protrude more than the sealing auxiliary groove EAG in a direction in which the roof portions RF face each other.

For example, an undercut structure UC may be formed between the roof portions RF and the second auxiliary groove ASG2 of the sealing auxiliary groove EAG.

A separation groove SPG may be formed by partially removing the pixel defining layer 132 exposed through the third opening OP3 of the second oxide mask layer OXML2.

The separation groove SPG may be formed concavely in the pixel defining layer 132.

As described above, according to embodiments, since the number of mask processes during the manufacturing process of the display device 100 may be reduced by preparing the separation groove SPG using the same mask process as the sealing auxiliary groove EAG, this may be advantageous in reducing manufacturing costs and improving yield of the display device 100.

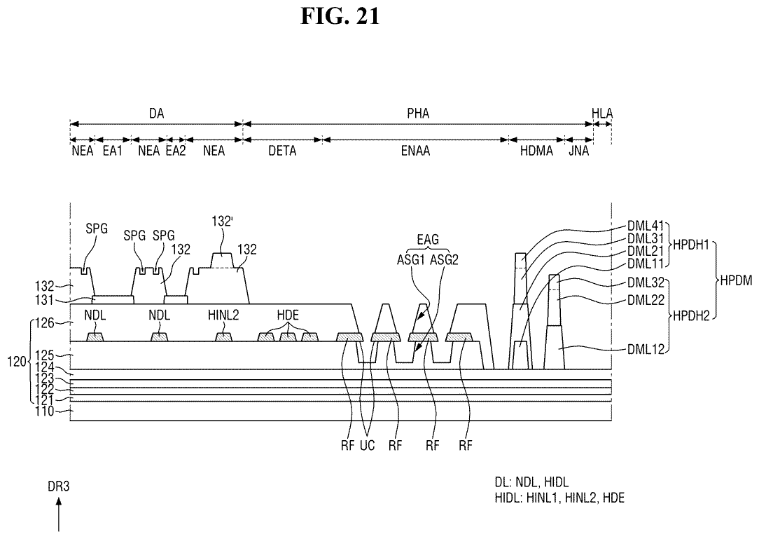

Referring to FIG. 21, after the sealing auxiliary groove EAG and the separation groove SPG are formed, the step of the removing of the second photo mask PMSK2 and the second oxide mask layer OXML2 (S337) may be performed.

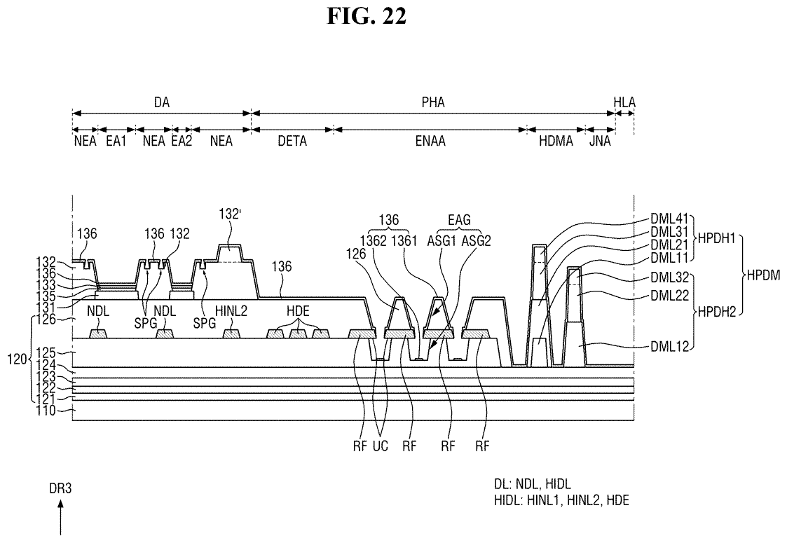

Referring to FIG. 22, in the step of the disposing of the first common layers 135 (S340), the first common layers 135 may be disposed by each stacking an organic material on the anode electrodes 131. Thereafter, in the step of the disposing of the light emitting layers 133 (S350), the light emitting layers 133 may be disposed by each stacking a light emitting material on the first common layers 135. Next, in the step of the disposing of the second common layer in the display area DA (S360), the second common layer 136 may be disposed by sequentially stacking an organic material covering the pixel defining layer 132, the spacer layer 132′, and the light emitting layers 133 over the entirety of the display area DA.

In this case, as the second common layer 136 is disposed to have a relatively thin width in the separation groove SPG of the display area DA, the second common layer 136 may be disconnected or separated by the separation groove SPG.

A portion of the second common layer 136 disposed in the hole peripheral area PHA may be separated by the undercut structure UC formed between the roof portions RF and the second auxiliary groove ASG2 of the sealing auxiliary groove EAG.

For example, a portion of the second common layer 136 disposed in the hole peripheral area PHA may include two or more first division portions 1361 disposed on the second planarization layer 126 and overlapping the two or more roof portions RF, and one or more second division portions 1362 disposed in the second auxiliary groove ASG2 of the one or more sealing auxiliary grooves EAG and spaced apart from the two or more first division portions 1361.

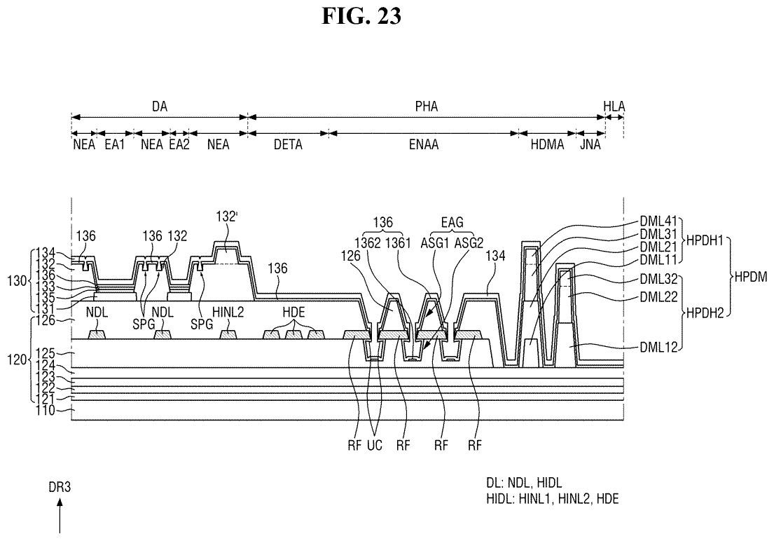

Referring to FIG. 23, in the step of the disposing of the cathode electrode 134 (S370), the cathode electrode 134 may be disposed by stacking a conductive material covering the second common layer 136. As an example, the cathode electrode 134 may include a transparent conductive material.

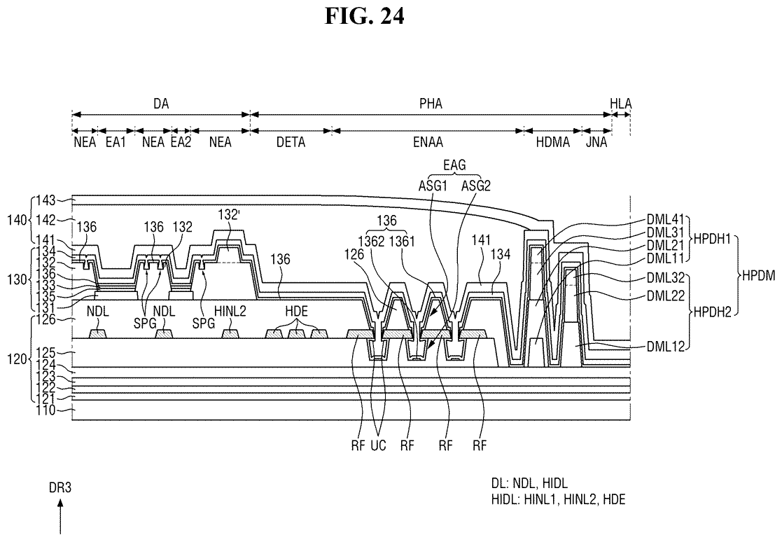

Referring to FIG. 24, in the step of the disposing of the sealing layer 140 (S40), the first sealing layer 141 covering the cathode electrode 134 of the element layer 130 may be disposed by stacking an inorganic insulating material entirely in the display area DA and the non-display area NDA, the second sealing layer 142 may be disposed by diffusing and then curing an organic insulating material dropped on the first sealing layer 141, and the third sealing layer 143 covering the second sealing layer 142 may be disposed by stacking an inorganic insulating material entirely in the display area DA and the non-display area NDA.

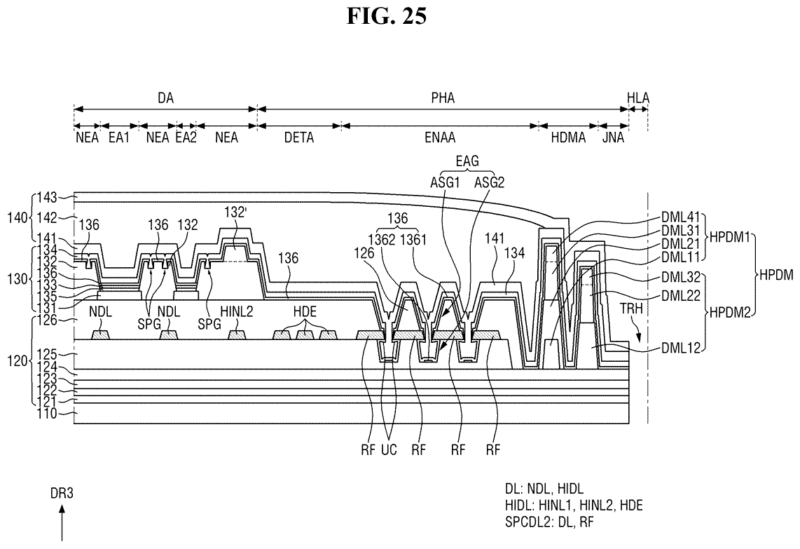

Referring to FIG. 25, in the step of the forming of the light transmitting hole TRH (S50), the light transmitting hole TRH may be disposed by partially removing the hole area HLA of the substrate 110 and a portion of each of the circuit layer 120, the element layer 130, and the sealing layer 140 overlapping thereon.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a substrate;
a circuit layer disposed on the substrate;
an element layer disposed on the circuit layer; and
a sealing layer disposed on the element layer, wherein
the display device includes a display area in which light emitting areas are arranged; a non-display area disposed adjacent to the display area; a hole area surrounded by the display area; and a hole peripheral area disposed between the hole area and the display area,
the circuit layer includes:
an interlayer insulating layer disposed on the substrate;
a first planarization layer disposed on the interlayer insulating layer;
roof portions disposed in the hole peripheral area on the first planarization layer and surrounding the hole area;
a second planarization layer disposed on the first planarization layer and covering the roof portions; and
one or more sealing auxiliary grooves positioned between adjacent ones of the roof portions,
each of the one or more sealing auxiliary grooves includes:
a first auxiliary groove penetrating through the second planarization layer; and
a second auxiliary groove formed concavely in the first planarization layer, and
a slope of a side surface of the second auxiliary groove with respect to the substrate is steeper than a slope of a side surface of the first auxiliary groove with respect to the substrate.

2. The display device of claim 1, wherein
in a direction in which the roof portions face each other, at least a portion of an edge of each of the roof portions protrudes more than the second auxiliary groove of the one or more sealing auxiliary grooves, and
an undercut structure is positioned between the roof portions and the second auxiliary groove of the one or more sealing auxiliary grooves.

3. The display device of claim 2, further comprising:
a light transmitting hole formed in the hole area and penetrating through the substrate, the circuit layer, the element layer, and the sealing layer.

4. The display device of claim 3, further comprising:
one or more hole peripheral dams disposed between the roof portions and the hole area and surrounding the hole area, wherein
the one or more hole peripheral dams are spaced apart from each of the first planarization layer, the second planarization layer, and the hole area,
the sealing layer includes:
a first sealing layer disposed on the element layer;
a second sealing layer disposed on the first sealing layer and overlapping the display area; and
a third sealing layer disposed on the first sealing layer and covering the second sealing layer,
the second sealing layer extends to the one or more hole peripheral dams and includes an organic insulating material spaced from the hole area,
the first sealing layer and the third sealing layer include an inorganic insulating material, and contact each other in an area between the one or more hole peripheral dams of the hole peripheral area and the hole area, and
the roof portions overlap the second sealing layer.

5. The display device of claim 4, wherein the element layer includes:
anode electrodes disposed in the light emitting areas;
a pixel defining layer disposed in a non-light emitting area adjacent to the light emitting areas and covering an edge of each of the anode electrodes;
a spacer layer disposed on a portion of the pixel defining layer;
first common layers disposed on the anode electrodes;
light emitting layers disposed on the first common layers;
a second common layer disposed in the display area and the hole peripheral area and covering the pixel defining layer, the spacer layer, and the light emitting layers; and
a cathode electrode disposed on the second common layer.

6. The display device of claim 5, wherein the element layer further includes a separation groove disposed around each of the light emitting areas and formed concavely in the pixel defining layer.

7. The display device of claim 6, wherein
the separation groove is parallel to each side of an edge of each of the light emitting areas, and
the second common layer is disconnected in the separation groove.

8. The display device of claim 5, wherein a portion of the second common layer disposed in the hole peripheral area includes:
first division portions disposed on the second planarization layer and overlapping the roof portions; and
one or more second division portions disposed within the second auxiliary groove of the one or more sealing auxiliary grooves and spaced apart from the first division portions.

9. The display device of claim 8, wherein within the second auxiliary groove of the one or more sealing auxiliary grooves, the cathode electrode contacts the first planarization layer.

10. The display device of claim 5, wherein each of the one or more hole peripheral dams includes dam layers, and
each of the dam layers and one of the first planarization layer, the second planarization layer, the pixel defining layer, and the spacer layer are disposed on a same layer.

11. The display device of claim 10, wherein in each of an area between the first planarization layer and the second planarization layer and the one or more hole peripheral dams, an area between the one or more hole peripheral dams, and an area between the one or more hole peripheral dams and the hole area, the first sealing layer contacts the interlayer insulating layer.

12. The display device of claim 5, wherein
the circuit layer further includes:
a first source drain conductive layer disposed in the display area on the interlayer insulating layer and covered by the first planarization layer; and
a second source drain conductive layer disposed in the display area on the first planarization layer and covered by the second planarization layer, and
the roof portions and the second source drain conductive layer are disposed on a same layer.

13. The display device of claim 5, wherein
the circuit layer further includes:
a buffer layer disposed on the substrate;
a first gate insulating layer disposed on the buffer layer; and
a second gate insulating layer disposed on the first gate insulating layer,
the interlayer insulating layer is disposed on the second gate insulating layer, and
the light transmitting hole penetrates through the third sealing layer, the first sealing layer, the cathode electrode, the second common layer, the interlayer insulating layer, the second gate insulating layer, the first gate insulating layer, the buffer layer, and the substrate.

14. A method for manufacturing a display device, the method comprising:
preparing a substrate including a display area in which light emitting areas are arranged; a non-display area disposed adjacent to the display area; a hole area surrounded by the display area; and a hole peripheral area disposed between the hole area and the display area;
disposing a circuit layer on the substrate;
disposing an element layer on the circuit layer;
disposing a sealing layer on the element layer; and
forming a light transmitting hole penetrating through the substrate, the circuit layer, the element layer, and the sealing layer in the hole area,
wherein the disposing of the element layer includes:
disposing anode electrodes of the light emitting areas on the circuit layer;
disposing a pixel defining layer of a non-light emitting area disposed adjacent to the light emitting areas on the circuit layer, and disposing a spacer layer on a portion of the pixel defining layer;
forming a sealing auxiliary groove in the hole peripheral area and a separation groove in the display area;
disposing first common layers on the anode electrodes;
disposing light emitting layers on the first common layers;
disposing a second common layer covering the pixel defining layer, the spacer layer, and the light emitting layers in the display area and the hole peripheral area; and
disposing a cathode electrode on the second common layer.

15. The display device of claim 14, wherein
the disposing of the circuit layer includes:
disposing an interlayer insulating layer on the substrate;
disposing a first source drain conductive layer in the display area on the interlayer insulating layer;
disposing a first planarization layer covering the first source drain conductive layer on the interlayer insulating layer;
disposing a second source drain conductive layer in the display area and roof portions in the hole peripheral area on the first planarization layer; and
disposing a second planarization layer covering the second source drain conductive layer and the roof portions on the first planarization layer,
in the disposing of the second source drain conductive layer and the roof portions, the roof portions surround the hole area, and
in the forming of the sealing auxiliary groove and the separation groove, the sealing auxiliary groove includes a first auxiliary groove positioned between the roof portions and penetrating through the second planarization layer, and a second auxiliary groove formed concavely in the first planarization layer, and the separation groove is positioned to surround each of the light emitting areas and is formed concavely in the pixel defining layer.

16. The display device of claim 15, wherein the forming of the sealing auxiliary groove and the separation groove includes:
disposing an oxide material layer covering the pixel defining layer in the display area and the second planarization layer in the hole peripheral area, and disposing a first photo mask on the oxide material layer;
preparing a first oxide mask layer by partially removing the oxide material layer through the first photo mask;
forming a first temporary groove penetrating through the second planarization layer and a second temporary groove formed concavely in the first planarization layer by partially removing the second planarization layer and the first planarization layer in the hole peripheral area through the first oxide mask layer;
preparing a second photo mask by partially removing the first photo mask;
preparing a second oxide mask layer by partially removing the first oxide mask layer through the second photo mask;
forming the separation groove by partially removing the pixel defining layer through the second oxide mask layer, and forming the sealing auxiliary groove by additionally removing the second planarization layer and the first planarization layer through the second oxide mask layer, the first temporary groove, and the second temporary groove; and
removing the second photo mask and the second oxide mask layer.

17. The display device of claim 16, wherein
in the disposing of the oxide material layer and the first photo mask, the first photo mask includes:
a first transmitting portion overlapping an area between the roof portions;
a first blocking portion overlapping a portion of the non-light emitting area adjacent to each of the light emitting areas and having a first thickness; and
a second blocking portion excluding the first transmitting portion and the first blocking portion and having a second thickness greater than the first thickness,
in the preparing of the first oxide mask layer, the first oxide mask layer includes
a first opening corresponding to the first transmitting portion, and
in the forming of the first temporary groove and the second temporary groove, the first temporary groove is formed by removing a portion of the second planarization layer through the first transmitting portion and the first opening, and the second temporary groove is formed by removing a portion of the first planarization layer through the first transmitting portion, the first opening, and the first temporary groove.

18. The display device of claim 17, wherein
in the preparing of the second photo mask, the second photo mask includes:
a second transmitting portion prepared by removing a portion of the second blocking portion disposed around the first transmitting portion;
a third transmitting portion prepared by removing the first blocking portion; and
a third blocking portion prepared as a remainder of the second blocking portion and having a third thickness smaller than the second thickness,
in the preparing of the second oxide mask layer, the second oxide mask layer includes a second opening corresponding to the second transmitting portion and a third opening corresponding to the third transmitting portion, and
in the forming of the sealing auxiliary groove and the separation groove, the first auxiliary groove is prepared by removing a portion of the second planarization layer disposed around the first temporary groove through the second opening, the second auxiliary groove is prepared by removing a portion of the first planarization layer disposed around the second temporary groove through the second opening and the first auxiliary groove, and the separation groove is prepared by removing a portion of the pixel defining layer through the third opening.

19. The display device of claim 18, wherein in the forming of the sealing auxiliary groove and the separation groove,
a slope of a side surface of the second auxiliary groove with respect to the substrate is steeper than a slope of a side surface of the first auxiliary groove with respect to the substrate,
in a direction in which the roof portions face each other, at least a portion of an edge of each of the roof portions protrudes more than the second auxiliary groove of the sealing auxiliary groove, and
an undercut structure is positioned between the roof portions and the second auxiliary groove of the sealing auxiliary groove.

20. The display device of claim 19, wherein
in the disposing of the second common layer, a portion of the second common layer disposed in the hole peripheral area includes:
first division portions disposed on the second planarization layer and overlapping the roof portions; and
one or more second division portions disposed within the second auxiliary groove of the sealing auxiliary groove and spaced apart from the first division portions, and
in the disposing of the cathode electrode, the cathode electrode contacts the first planarization layer within the second auxiliary groove of the sealing auxiliary groove.
